(19) United States
(12) Patent Application Publication
(10) Pub. No.: US 2026/0229300 A1
(43) Pub. Date: Aug. 6, 2026

(54) MULTI-PASS PROGRAMMING TECHNIQUES FOR MEMORY DEVICES

(71) Applicant: Sandisk Technologies, Inc., Milpitas, CA (US)

(72) Inventors: Zhenni Wan, San Jose, CA (US); Bo Lei, San Jose, CA (US); Ken Oowada, Fujisawa, Kanagawa (JP)

(21) Appl. No.: 19/046,046

(22) Filed: Feb. 5, 2025

(51) Int. Cl. G11C 16/34; G11C 16/10; G11C 16/26; G11C 29/52

(52) U.S. Cl. CPC G11C 16/3459; G11C 16/102; G11C 16/26; G11C 29/52

(57) ABSTRACT

The memory device includes memory blocks with arrays of memory cells that are arranged in word lines. Circuitry is configured to program four pages of user data into the memory cells of a selected word line of a selected memory block in a multi-pass programming operation. In a first programming pass, the circuitry programs foggy data into the memory cells of the selected word line. In at least one parity memory block, the circuitry programs two pages of parity data. Prior to a second programming pass, the circuitry reads the foggy data to retrieve two pages of user data and reads the parity data to retrieve the other two pages of user data. The circuitry then combines the pages from the foggy data and the pages from the selected word line to recreate the four pages of user data.

### BACKGROUND

### 1. Field

The subject disclosure is related generally to memory devices and, more particularly, to improved programming techniques to improve performance and reduce the use of host resources.

### 2. Related Art

Semiconductor memory is widely used in various electronic devices, such as cellular telephones, digital cameras, personal digital assistants, medical electronics, mobile computing devices, servers, solid state drives, non-mobile computing devices and other devices. Semiconductor memory may comprise non-volatile memory or volatile memory. A non-volatile memory allows information to be stored and retained even when the non-volatile memory is not connected to a source of power, e.g., a battery.

NAND memory devices include a chip with a plurality of memory blocks, each of which includes an array of memory cells arranged in a plurality of word lines. The memory cells can be programmed to have threshold voltages that are associated with data states in a programming operation. In some cases, the memory cells are programmed directly to the threshold voltages associated with their intended programmed data states in a full-sequence programming operation. In some other cases, the memory cells are programmed to their final threshold voltages in two or more programming passes, each of which includes a plurality of program loops.

### SUMMARY

One aspect of the present disclosure is related to a method of programming a memory device. The method includes the step of preparing a plurality of memory blocks. Each of the memory blocks includes an array of memory cells that are arranged in a plurality of word lines. In a selected memory block of the plurality of memory blocks, in a first programming pass, the method proceeds with the step of programming foggy data into the memory cells of a selected word line of the plurality of word lines. In at least one parity memory block of the plurality of memory blocks, the method continues with the step of programming two pages of parity data. The method proceeds with the step of reading the foggy data to retrieve two pages pages of user data. The method continues with the step of reading the parity data to retrieve two other pages of user data. The method proceeds with the step of combining the two pages of user data from the foggy data and the two other pages of user data to recreate four pages of user data.

According to another aspect of the present disclosure, the method further includes the step of in a second programming pass, programming the memory cells of the selected word line from the foggy data to the user data.

According to yet another aspect of the present disclosure, the method further includes the step of reading the foggy data to retrieve the two pages of user data includes performing sensing operations at no more than three read levels.

According to still another aspect of the present disclosure, the step of, in the first programming pass, programming the foggy data into the memory cells of the selected word line further includes performing a plurality of verify operations at only three checkpoint data states.

According to a further aspect of the present disclosure, the step of, in the first programming pass, programming the foggy data into the memory cells of the selected word line further includes performing at least one program loop that includes a programming pulse and does not include a verify pulse.

According to yet a further aspect of the present disclosure, following the first pass, the memory cells of the selected word line are divided into four groups and the groups are divided into different threshold voltage ranges.

According to still a further aspect of the present disclosure, prior to the second programming pass, the method further includes the step of, in a single programming pulse, inhibiting some of the memory cells of one of the four groups, programming some of the memory cells of the one of the four groups at a first rate, and programming some of the memory cells of the one of the four groups at a second rate that is greater than the first rate.

Another aspect of the present disclosure is related to a memory device that includes a plurality of memory blocks. Each of the memory blocks has an array of memory cells that are arranged in a plurality of word lines. The memory device also includes circuitry that is configured to program four pages of user data into the memory cells of a selected word line of the plurality of word lines and in a selected memory block of the plurality of memory blocks in a multi-pass programming operation. The circuitry is configured to, in a first programming pass, program foggy data into the memory cells of a selected word line of the plurality of word lines. The circuitry is further configured, in at least one parity memory block of the plurality of memory blocks, to program two pages of parity data. The circuitry is also configured to read the foggy data to retrieve two pages pages of user data, read the parity data to retrieve two other pages of user data, and combine the two pages of user data from the foggy data and the two other pages of user data to recreate four pages of user data.

According to another aspect of the present disclosure, during a second programming pass, the circuitry is further configured to program the memory cells of the selected word line from the foggy data to the user data.

According to yet another aspect of the present disclosure, when reading the foggy data to retrieve the two pages of user data, the circuitry performs sensing operations at no more than three read levels.

According to still another aspect of the present disclosure, while programming the foggy data into the memory cells of the selected word line, the circuitry is further configured to perform a plurality of verify operations at only three checkpoint data states.

According to a further aspect of the present disclosure, while programming the foggy data into the memory cells of the selected word line, the circuitry is configured to perform at least one program loop that includes a programming pulse and does not include a verify pulse.

According to yet a further aspect of the present disclosure, following the first pass, the memory cells of the selected word line are divided into four groups and the groups are divided into different threshold voltage ranges.

According to still a further aspect of the present disclosure, prior to the second programming pass, the circuitry is configured to, in a single programming pulse, inhibit some of the memory cells of one of the four groups, program some of the memory cells of the one of the four groups at a first rate, and program some of the memory cells of the one of the four groups at a second rate that is greater than the first rate.

Yet another aspect of the present is related to an apparatus that includes a plurality of memory blocks. Each of the memory blocks has an array of memory cells that are arranged in a plurality of word lines. The apparatus also includes a programming means for programming the memory cells of a selected word line of the plurality of word lines to include four pages of user data per memory cell in a first programming pass and a second programming pass. The programming means is configured to, in a first programming pass, program foggy data into the memory cells of a selected word line of the plurality of word lines. The foggy data includes two pages of the four pages of user data. The programming means is also configured to, in at least one parity memory block of the plurality of memory blocks, program two pages of parity data. The two pages of parity data includes two other pages of the four pages of user data. The programming means is further configured to ead the foggy data to retrieve the two pages pages of user data, read the parity data to retrieve the two other pages of user data, and combine the two pages of user data from the foggy data and the two other pages of user data to recreate four pages of user data. The programming means is also configured to in a second programming pass, program the other two pages of user data into the selected word line.

According to another aspect of the present disclosure, when reading the foggy data to retrieve the two pages of user data, the programming means performs sensing operations at no more than three read levels.

According to yet another aspect of the present disclosure, while programming the foggy data into the memory cells of the selected word line, the programming means is further configured to perform a plurality of verify operations at only three checkpoint data states.

According to still another aspect of the present disclosure, while programming the foggy data into the memory cells of the selected word line, the programming means is configured to perform at least one program loop that includes a programming pulse and does not include a verify pulse.

According to a further aspect of the present disclosure, following the first pass, the memory cells of the selected word line are divided into four groups and the groups are divided into different threshold voltage ranges.

According to yet a further aspect of the present disclosure, prior to the second programming pass, the programming means is configured to, in a single programming pulse, inhibit some of the memory cells of one of the four groups, program some of the memory cells of the one of the four groups at a first rate, and program some of the memory cells of the one of the four groups at a second rate that is greater than the first rate.

### BRIEF DESCRIPTION OF THE DRAWINGS

A more detailed description is set forth below with reference to example embodiments depicted in the appended figures. Understanding that these figures depict only example embodiments of the disclosure and are, therefore, not to be considered limiting of its scope. The disclosure is described and explained with added specificity and detail through the use of the accompanying drawings in which:

FIG. 1A is a block diagram of an example memory device;

FIG. 1B is a block diagram of an example control circuit;

FIG. 2 depicts blocks of memory cells in an example two-dimensional configuration of the memory array of FIG. 1A;

FIG. 3A and FIG. 3B depict cross-sectional views of example floating gate memory cells in NAND strings;

FIG. 4A and FIG. 4B depict cross-sectional views of example charge-trapping memory cells in NAND strings;

FIG. 5 depicts an example block diagram of the sense block SB1 of FIG. 1;

FIG. 6A is a perspective view of a set of blocks in an example three-dimensional configuration of the memory array of FIG. 1;

FIG. 6B depicts an example cross-sectional view of a portion of one of the blocks of FIG. 6A;

FIG. 6C depicts a plot of memory hole diameter in the stack of FIG. 6B;

FIG. 6D depicts a close-up view of region 622 of the stack of FIG. 6B;

FIG. 7A depicts a top view of an example word line layer WL0 of the stack of FIG. 6B;

FIG. 7B depicts a top view of an example top dielectric layer DL116 of the stack of FIG. 6B;

FIG. 8 depicts a threshold voltage Vt distribution plot of a plurality of memory cells programmed according to a one bit per memory cell (SLC) storage scheme;

FIG. 9 depicts a threshold voltage Vt distribution plot of a plurality of memory cells programmed according to a two bits per memory cell (MLC) storage scheme;

FIG. 10 depicts a threshold voltage Vt distribution plot of a plurality of memory cells programmed according to a four bits per memory cell (QLC) storage scheme;

FIG. 11 is a voltage waveform of a selected word line during an example programming operation;

FIG. 12 is a threshold voltage Vt distribution plot depicting one type of multi-pass programming operation;

FIG. 13 is a threshold voltage Vt distribution plot depicting another type of multi-pass programming operation;

FIG. 14 is a threshold voltage Vt distribution plot depicting a plurality of memory cells that are programmed to contain foggy data according to an exemplary embodiment of the present disclosure;

FIG. 15A is a schematic view illustrating a plurality of memory blocks in a plane according to one example embodiment;

FIG. 15B is a schematic view illustrating a plurality of memory blocks in a plane according to another example embodiment;

FIG. 16 is a table depicting four pages of data (lower page, middle page, upper page, and top page) and the bits for the sixteen data states;

FIG. 17 includes threshold voltage distribution plots of a first group of memory cells following a foggy pass, a first H-Pulse, and a fine pass;

FIG. 18 includes threshold voltage distribution plots of a second group of memory cells following the foggy pass, a second H-Pulse, and the fine pass;

FIG. 19 includes threshold voltage distribution plots of a third group of memory cells following the foggy pass, a third H-Pulse, and the fine pass;

FIG. 20 illustrates the voltages applied to a selected word line and many of the bit lines of a memory block during the first H-Pulse; and

FIG. 21 is a flow chart depicting the steps of programming the memory cells of a selected word line according to an exemplary embodiment of the present disclosure.

### DESCRIPTION OF THE ENABLING EMBODIMENTS

The present disclosure is related to improved multi-pass programming techniques for a memory device for programming four pages of user data into the memory cells of a selected word line within a selected memory block. According to one aspect of the present disclosure, a first (foggy) programming pass is performed on a selected word line in such a way that the foggy data includes two of the four pages of user data. The other two pages of user data are programmed as parity data in parity blocks of the same memory device. Then, prior to a second (fine) programming pass, an internal data latch (IDL) read operation is performed on the foggy data to retrieve the first two pages of user data and the parity data is read to retrieve the other two pages of user data. With the four pages of user data having been retrieved, the fine pass can then be performed to program the memory cells of the selected word line from the foggy data to the user data.

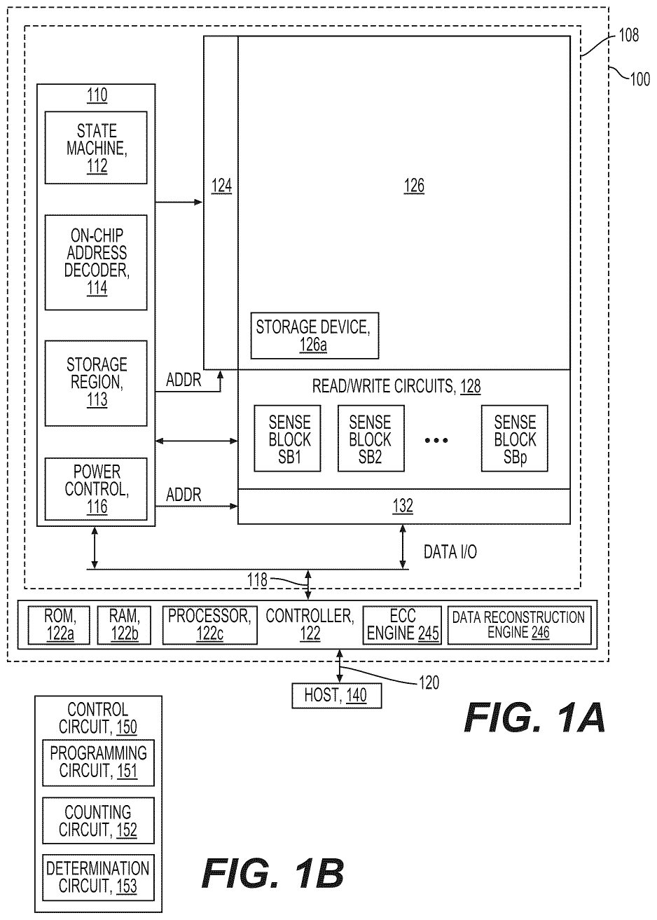

FIG. 1A is a block diagram of an example memory device 100 is configured to program the memory cells of a memory block according to the programming techniques of the subject disclosure. The memory die 108 includes a memory structure 126 of memory cells, such as an array of memory cells, control circuitry 110, and read/write circuits 128. The memory structure 126 is addressable by word lines via a row decoder 124 and by bit lines via a column decoder 132. The read/write circuits 128 include multiple sense blocks SB1, SB2,. SBp (sensing circuitry) and allow a page of memory cells to be read or programmed in parallel. Typically, a controller 122 is included in the same memory device 100 (e.g., a removable storage card) as the one or more memory die 108. Commands and data are transferred between the host 140 and controller 122 via a data bus 120, and between the controller and the one or more memory die 108 via lines 118.

The memory structure 126 can be two-dimensional or three-dimensional. The memory structure 126 may comprise one or more array of memory cells including a three-dimensional array. The memory structure 126 may comprise a monolithic three-dimensional memory structure in which multiple memory levels are formed above (and not in) a single substrate, such as a wafer, with no intervening substrates. The memory structure 126 may comprise any type of non-volatile memory that is monolithically formed in one or more physical levels of arrays of memory cells having an active area disposed above a silicon substrate. The memory structure 126 may be in a non-volatile memory device having circuitry associated with the operation of the memory cells, whether the associated circuitry is above or within the substrate.

The control circuitry 110 cooperates with the read/write circuits 128 to perform memory operations on the memory structure 126, and includes a state machine 112, an on-chip address decoder 114, and a power control module 116. The state machine 112 provides chip-level control of memory operations.

A storage region 113 may, for example, be provided for programming parameters. The programming parameters may include a program voltage, a program voltage bias, position parameters indicating positions of memory cells, contact line connector thickness parameters, a verify voltage, and/or the like. The position parameters may indicate a position of a memory cell within the entire array of NAND strings, a position of a memory cell as being within a particular NAND string group, a position of a memory cell on a particular plane, and/or the like. The contact line connector thickness parameters may indicate a thickness of a contact line connector, a substrate or material that the contact line connector is comprised of, and/or the like.

The on-chip address decoder 114 provides an address interface between that used by the host or a memory controller to the hardware address used by the decoders 124 and 132. The power control module 116 controls the power and voltages supplied to the word lines and bit lines during memory operations. It can include drivers for word lines, SGS and SGD transistors, and source lines. The sense blocks can include bit line drivers, in one approach. An SGS transistor is a select gate transistor at a source end of a NAND string, and an SGD transistor is a select gate transistor at a drain end of a NAND string.

In some embodiments, some of the components can be combined. In various designs, one or more of the components (alone or in combination), other than memory structure 126, can be thought of as at least one control circuit which is configured to perform the actions described herein. For example, a control circuit may include any one of, or a combination of, control circuitry 110, state machine 112, decoders 114/132, power control module 116, sense blocks SBb, SB2, . . . SBp, read/write circuits 128, controller 122, and so forth.

The control circuits 150 can include a programming circuit 151 configured to perform a program and verify operation for one set of memory cells, wherein the one set of memory cells comprises memory cells assigned to represent one data state among a plurality of data states and memory cells assigned to represent another data state among the plurality of data states; the program and verify operation comprising a plurality of program and verify iterations; and in each program and verify iteration, the programming circuit performs programming for the one selected word line after which the programming circuit applies a verification signal to the selected word line. The control circuits 150 can also include a counting circuit 152 configured to obtain a count of memory cells which pass a verify test for the one data state. The control circuits 150 can also include a determination circuit 153 configured to determine, based on an amount by which the count exceeds a threshold, if a programming operation is completed.

For example, FIG. 1B is a block diagram of an example control circuit 150 which comprises the programming circuit 151, the counting circuit 152, and the determination circuit 153.

The off-chip controller 122 may comprise a processor 122c, storage devices (memory) such as ROM 122a and RAM 122b, an error-correction code (ECC) engine 245, and a data reconstruction engine 246. The ECC engine can correct a number of read errors that are caused when the upper tail of a Vt distribution becomes too high. However, uncorrectable errors may exist in some cases. The techniques provided herein reduce the likelihood of uncorrectable errors.

The storage device(s) 122a, 122b comprise, code such as a set of instructions, and the processor 122c is operable to execute the set of instructions to provide the functionality described herein. Alternately or additionally, the processor 122c can access code from a storage device 126a of the memory structure 126, such as a reserved area of memory cells in one or more word lines. For example, code can be used by the controller 122 to access the memory structure 126 such as for programming, read and erase operations. The code can include boot code and control code (e.g., set of instructions). The boot code is software that initializes the controller 122 during a booting or startup process and enables the controller 122 to access the memory structure 126. The code can be used by the controller 122 to control one or more memory structures 126. Upon being powered up, the processor 122c fetches the boot code from the ROM 122a or storage device 126a for execution, and the boot code initializes the system components and loads the control code into the RAM 122b. Once the control code is loaded into the RAM 122b, it is executed by the processor 122c. The control code includes drivers to perform basic tasks such as controlling and allocating memory, prioritizing the processing of instructions, and controlling input and output ports.

Generally, the control code can include instructions to perform the functions described herein including the steps of the flowcharts discussed further below and provide the voltage waveforms including those discussed further below.

In one embodiment, the host is a computing device (e.g., laptop, desktop, smartphone, tablet, digital camera) that includes one or more processors, one or more processor readable storage devices (RAM, ROM, flash memory, hard disk drive, solid state memory) that store processor readable code (e.g., software) for programming the one or more processors to perform the methods described herein. The host may also include additional system memory, one or more input/output interfaces and/or one or more input/output devices in communication with the one or more processors.

Other types of non-volatile memory in addition to NAND flash memory can also be used.

Semiconductor memory devices include volatile memory devices, such as dynamic random access memory (“DRAM”) or static random access memory (“SRAM”) devices, non-volatile memory devices, such as resistive random access memory (“ReRAM”), electrically erasable programmable read only memory (“EEPROM”), flash memory (which can also be considered a subset of EEPROM), ferroelectric random access memory (“FRAM”), and magnetoresistive random access memory (“MRAM”), and other semiconductor elements capable of storing information. Each type of memory device may have different configurations. For example, flash memory devices may be configured in a NAND or a NOR configuration.

The memory devices can be formed from passive and/or active elements, in any combinations. By way of non-limiting example, passive semiconductor memory elements include ReRAM device elements, which in some embodiments include a resistivity switching storage element, such as an anti-fuse or phase change material, and optionally a steering element, such as a diode or transistor. Further by way of non-limiting example, active semiconductor memory elements include EEPROM and flash memory device elements, which in some embodiments include elements containing a charge storage region, such as a floating gate, conductive nanoparticles, or a charge storage dielectric material.

Multiple memory elements may be configured so that they are connected in series or so that each element is individually accessible. By way of non-limiting example, flash memory devices in a NAND configuration (NAND memory) typically contain memory elements connected in series. A NAND string is an example of a set of series-connected transistors comprising memory cells and SG transistors.

A NAND memory array may be configured so that the array is composed of multiple memory strings in which a string is composed of multiple memory elements sharing a single bit line and accessed as a group. Alternatively, memory elements may be configured so that each element is individually accessible, e.g., a NOR memory array. NAND and NOR memory configurations are examples, and memory elements may be otherwise configured. The semiconductor memory elements located within and/or over a substrate may be arranged in two or three dimensions, such as a two-dimensional memory structure or a three-dimensional memory structure.

In a two-dimensional memory structure, the semiconductor memory elements are arranged in a single plane or a single memory device level. Typically, in a two-dimensional memory structure, memory elements are arranged in a plane (e.g., in an x-y direction plane) which extends substantially parallel to a major surface of a substrate that supports the memory elements. The substrate may be a wafer over or in which the layer of the memory elements is formed or it may be a carrier substrate which is attached to the memory elements after they are formed. As a non-limiting example, the substrate may include a semiconductor such as silicon.

The memory elements may be arranged in the single memory device level in an ordered array, such as in a plurality of rows and/or columns. However, the memory elements may be arrayed in non-regular or non-orthogonal configurations. The memory elements may each have two or more electrodes or contact lines, such as bit lines and word lines.

A three-dimensional memory array is arranged so that memory elements occupy multiple planes or multiple memory device levels, thereby forming a structure in three dimensions (i.e., in the x, y and z directions, where the z-direction is substantially perpendicular and the x-and y-directions are substantially parallel to the major surface of the substrate).

As a non-limiting example, a three-dimensional memory structure may be vertically arranged as a stack of multiple two-dimensional memory device levels. As another non-limiting example, a three-dimensional memory array may be arranged as multiple vertical columns (e.g., columns extending substantially perpendicular to the major surface of the substrate, i.e., in the y direction) with each column having multiple memory elements. The columns may be arranged in a two-dimensional configuration, e.g., in an x-y plane, resulting in a three-dimensional arrangement of memory elements with elements on multiple vertically stacked memory planes. Other configurations of memory elements in three dimensions can also constitute a three-dimensional memory array.

By way of non-limiting example, in a three-dimensional array of NAND strings, the memory elements may be coupled together to form a NAND string within a single horizontal (e.g., x-y) memory device level. Alternatively, the memory elements may be coupled together to form a vertical NAND string that traverses across multiple horizontal memory device levels. Other three-dimensional configurations can be envisioned wherein some NAND strings contain memory elements in a single memory level while other strings contain memory elements which span through multiple memory levels. Three-dimensional memory arrays may also be designed in a NOR configuration and in a ReRAM configuration.

Typically, in a monolithic three-dimensional memory array, one or more memory device levels are formed above a single substrate. Optionally, the monolithic three-dimensional memory array may also have one or more memory layers at least partially within the single substrate. As a non-limiting example, the substrate may include a semiconductor such as silicon. In a monolithic three-dimensional array, the layers constituting each memory device level of the array are typically formed on the layers of the underlying memory device levels of the array. However, layers of adjacent memory device levels of a monolithic three-dimensional memory array may be shared or have intervening layers between memory device levels.

Then again, two-dimensional arrays may be formed separately and then packaged together to form a non-monolithic memory device having multiple layers of memory. For example, non-monolithic stacked memories can be constructed by forming memory levels on separate substrates and then stacking the memory levels atop each other. The substrates may be thinned or removed from the memory device levels before stacking, but as the memory device levels are initially formed over separate substrates, the resulting memory arrays are not monolithic three-dimensional memory arrays. Further, multiple two-dimensional memory arrays or three-dimensional memory arrays (monolithic or non-monolithic) may be formed on separate chips and then packaged together to form a stacked-chip memory device.

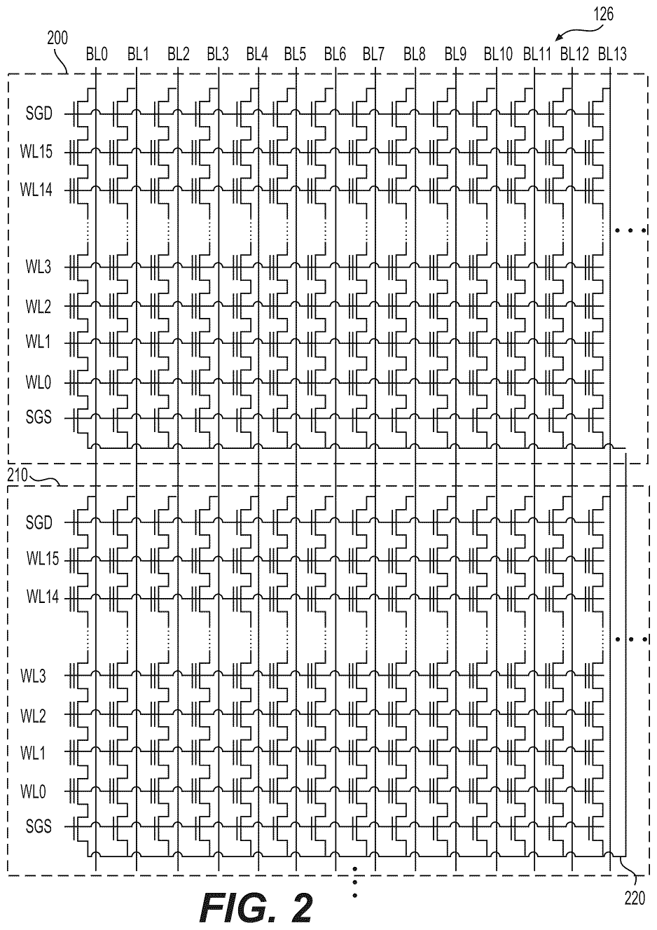

FIG. 2 illustrates memory blocks 200, 210 of memory cells in an example two-dimensional configuration of the memory array 126 of FIG. 1. The memory array 126 can include many such blocks 200, 210. Each example block 200, 210 includes a number of NAND strings and respective bit lines, e.g., BL0, BL1, . . . which are shared among the blocks. Each NAND string is connected at one end to a drain-side select gate (SGD), and the control gates of the drain-side select gates are connected via a common SGD line. The NAND strings are connected at their other end to a source-side select gate (SGS) which, in turn, is connected to a common source line 220. One hundred and twelve word lines, for example, WL0-WL111, extend between the SGSs and the SGDs. In some embodiments, the memory block may include more or fewer than one hundred and twelve word lines. For example, in some embodiments, a memory block includes one hundred and sixty-four word lines. In some cases, dummy word lines, which contain no user data, can also be used in the memory array adjacent to the select gate transistors or between certain data word lines. Such dummy word lines can shield the edge data word line from certain edge effects.

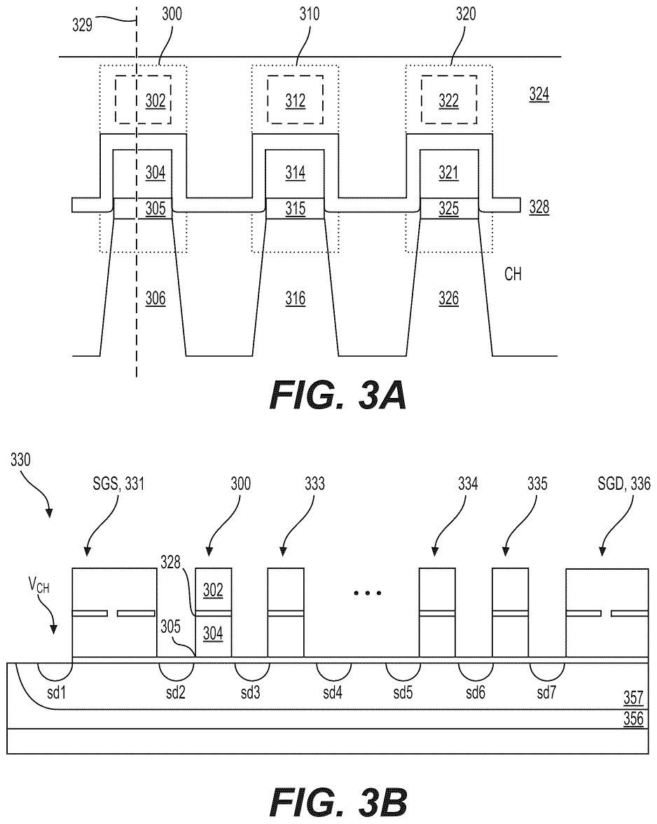

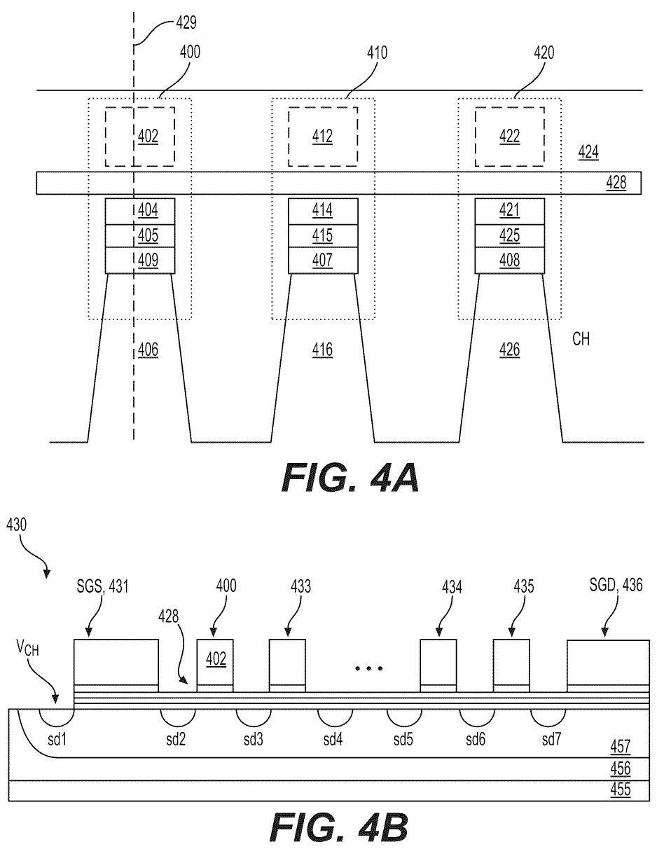

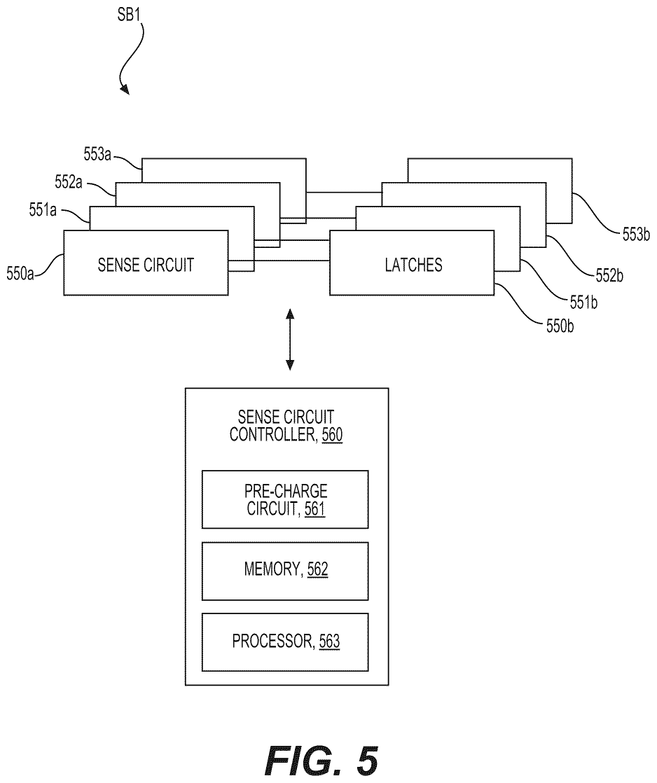

One type of non-volatile memory which may be provided in the memory array is a floating gate memory, such as of the type shown in FIGS. 3A and 3B. However, other types of non-volatile memory can also be used. As discussed in further detail below, in another example shown in FIGS. 4A and 4B, a charge-trapping memory cell uses a non-conductive dielectric material in place of a conductive floating gate to store charge in a non-volatile manner. A triple layer dielectric formed of silicon oxide, silicon nitride and silicon oxide (“ONO”) is sandwiched between a conductive control gate and a surface of a semi-conductive substrate above the memory cell channel. The cell is programmed by injecting electrons from the cell channel into the nitride, where they are trapped and stored in a limited region. This stored charge then changes the threshold voltage of a portion of the channel of the cell in a manner that is detectable. The cell is erased by injecting hot holes into the nitride. A similar cell can be provided in a split-gate configuration where a doped polysilicon gate extends over a portion of the memory cell channel to form a separate select transistor.

In another approach, NROM cells are used. Two bits, for example, are stored in each NROM cell, where an ONO dielectric layer extends across the channel between source and drain diffusions. The charge for one data bit is localized in the dielectric layer adjacent to the drain, and the charge for the other data bit localized in the dielectric layer adjacent to the source. Multi-state data storage is obtained by separately reading binary states of the spatially separated charge storage regions within the dielectric. Other types of non-volatile memory are also known.

FIG. 3A illustrates a cross-sectional view of example floating gate memory cells 300, 310, 320 in NAND strings. In this Figure, a bit line or NAND string direction goes into the page, and a word line direction goes from left to right. As an example, word line 324 extends across NAND strings which include respective channel regions 306, 316 and 326. The memory cell 300 includes a control gate 302, a floating gate 304, a tunnel oxide layer 305 and the channel region 306. The memory cell 310 includes a control gate 312, a floating gate 314, a tunnel oxide layer 315 and the channel region 316. The memory cell 320 includes a control gate 322, a floating gate 321, a tunnel oxide layer 325 and the channel region 326. Each memory cell 300, 310, 320 is in a different respective NAND string. An inter-poly dielectric (IPD) layer 328 is also illustrated. The control gates 302, 312, 322 are portions of the word line. A cross-sectional view along contact line connector 329 is provided in FIG. 3B.

The control gate 302, 312, 322 wraps around the floating gate 304, 314, 321, increasing the surface contact area between the control gate 302, 312, 322 and floating gate 304, 314, 321. This results in higher IPD capacitance, leading to a higher coupling ratio which makes programming and erase easier. However, as NAND memory devices are scaled down, the spacing between neighboring cells 300, 310, 320 becomes smaller so there is almost no space for the control gate 302, 312, 322 and the IPD layer 328 between two adjacent floating gates 302, 312, 322.

As an alternative, as shown in FIGS. 4A and 4B, the flat or planar memory cell 400, 410, 420 has been developed in which the control gate 402, 412, 422 is flat or planar; that is, it does not wrap around the floating gate and its only contact with the charge storage layer 428 is from above it. In this case, there is no advantage in having a tall floating gate. Instead, the floating gate is made much thinner. Further, the floating gate can be used to store charge, or a thin charge trap layer can be used to trap charge. This approach can avoid the issue of ballistic electron transport, where an electron can travel through the floating gate after tunneling through the tunnel oxide during programming.

FIG. 4A depicts a cross-sectional view of example charge-trapping memory cells 400, 410, 420 in NAND strings. The view is in a word line direction of memory cells 400, 410, 420 comprising a flat control gate and charge-trapping regions as a two-dimensional example of memory cells 400, 410, 420 in the memory cell array 126 of FIG. 1. Charge-trapping memory can be used in NOR and NAND flash memory device. This technology uses an insulator such as an SiN film to store electrons, in contrast to a floating-gate MOSFET technology which uses a conductor such as doped polycrystalline silicon to store electrons. As an example, a word line 424 extends across NAND strings which include respective channel regions 406, 416, 426. Portions of the word line provide control gates 402, 412, 422. Below the word line is an IPD layer 428, charge-trapping layers 404, 414, 421, polysilicon layers 405, 415, 425, and tunneling layers 409, 407, 408. Each charge-trapping layer 404, 414, 421 extends continuously in a respective NAND string. The flat configuration of the control gate can be made thinner than a floating gate. Additionally, the memory cells can be placed closer together.

FIG. 4B illustrates a cross-sectional view of the structure of FIG. 4A along contact line connector 429. The NAND string 430 includes an SGS transistor 431, example memory cells 400, 433,. 435, and an SGD transistor 436. Passageways in the IPD layer 428 in the SGS and SGD transistors 431, 436 allow the control gate layers 402 and floating gate layers to communicate. The control gate 402 and floating gate layers may be polysilicon and the tunnel oxide layer may be silicon oxide, for instance. The IPD layer 428 can be a stack of nitrides (N) and oxides (O) such as in a N—O—N—O—N configuration.

The NAND string may be formed on a substrate which comprises a p-type substrate region 455, an n-type well 456 and a p-type well 457. N-type source/drain diffusion regions sd1, sd2, sd3, sd4, sd5, sd6 and sd7 are formed in the p-type well. A channel voltage, Vch, may be applied directly to the channel region of the substrate.

FIG. 5 illustrates an example block diagram of the sense block SB1 of FIG. 1. In one approach, a sense block comprises multiple sense circuits. Each sense circuit is associated with data latches. For example, the example sense circuits 550a, 551a, 552a, and 553a are associated with the data latches 550b, 551b, 552b, and 553b, respectively. In one approach, different subsets of bit lines can be sensed using different respective sense blocks. This allows the processing load which is associated with the sense circuits to be divided up and handled by a respective processor in each sense block. For example, a sense circuit controller 560 in SB1 can communicate with the set of sense circuits and latches. The sense circuit controller 560 may include a pre-charge circuit 561 which provides a voltage to each sense circuit for setting a pre-charge voltage. In one possible approach, the voltage is provided to each sense circuit independently, e.g., via the data bus and a local bus. In another possible approach, a common voltage is provided to each sense circuit concurrently. The sense circuit controller 560 may also include a pre-charge circuit 561, a memory 562 and a processor 563. The memory 562 may store code which is executable by the processor to perform the functions described herein. These functions can include reading the latches 550b, 551b, 552b, 553b which are associated with the sense circuits 550a, 551a, 552a, 553a, setting bit values in the latches and providing voltages for setting pre-charge levels in sense nodes of the sense circuits 550a, 551a, 552a, 553a. Further example details of the sense circuit controller 560 and the sense circuits 550a, 551a, 552a, 553a are provided below.

In some embodiments, a memory cell may include a flag register that includes a set of latches storing flag bits. In some embodiments, a quantity of flag registers may correspond to a quantity of data states. In some embodiments, one or more flag registers may be used to control a type of verification technique used when verifying memory cells. In some embodiments, a flag bit's output may modify associated logic of the device, e.g., address decoding circuitry, such that a specified block of cells is selected. A bulk operation (e.g., an erase operation, etc.) may be carried out using the flags set in the flag register, or a combination of the flag register with the address register, as in implied addressing, or alternatively by straight addressing with the address register alone.

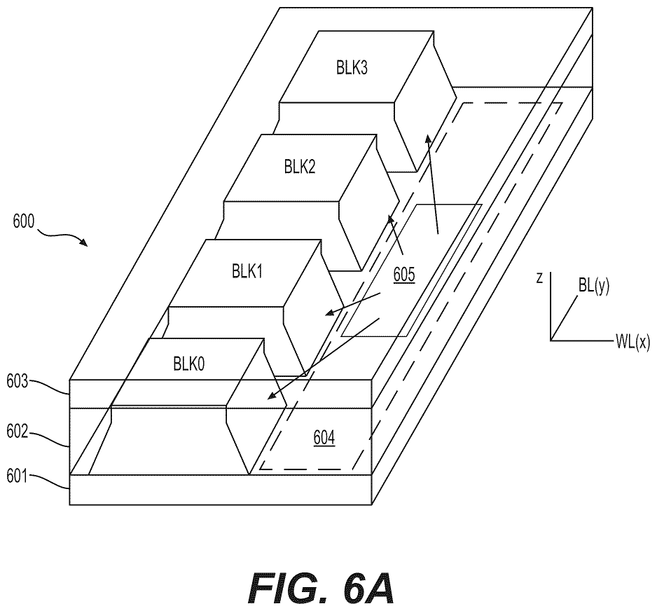

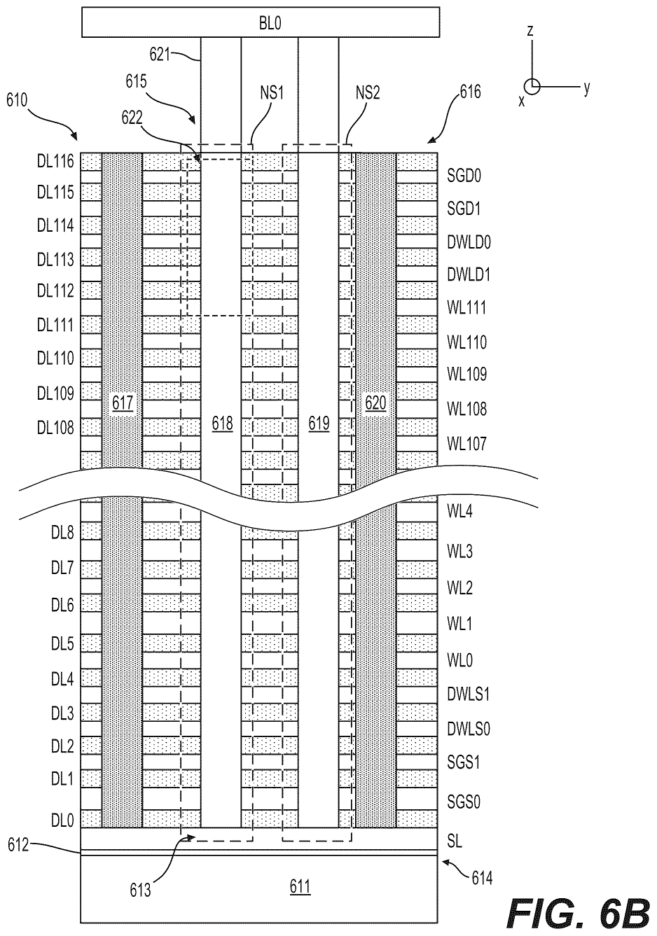

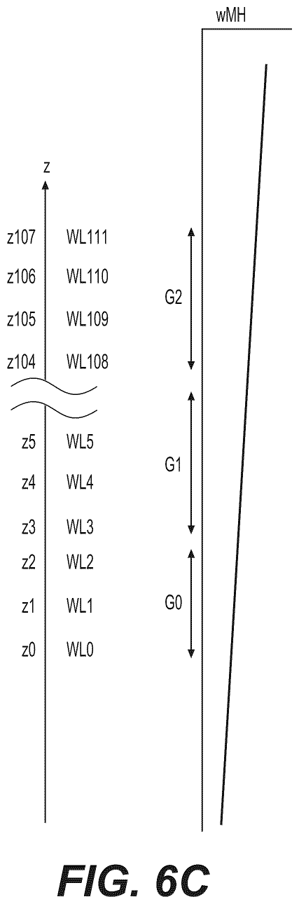

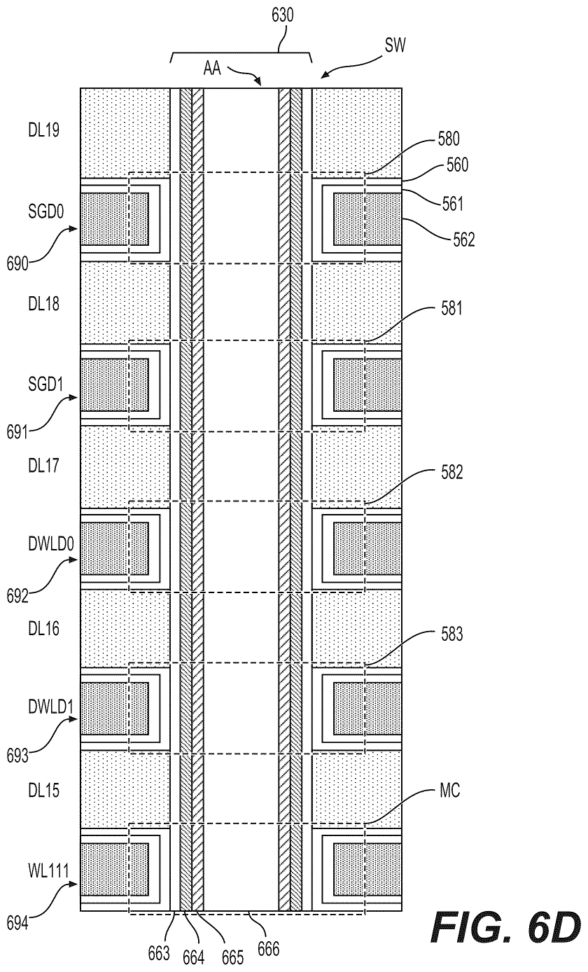

FIG. 6A is a perspective view of a set of blocks 600 in an example three-dimensional configuration of the memory array 126 of FIG. 1. On the substrate are example blocks BLK0, BLK1, BLK2, BLK3 of memory cells (storage elements) and a peripheral area 604 with circuitry for use by the blocks BLK0, BLK1, BLK2, BLK3. For example, the circuitry can include voltage drivers 605 which can be connected to control gate layers of the blocks BLK0, BLK1, BLK2, BLK3. In one approach, control gate layers at a common height in the blocks BLK0, BLK1, BLK2, BLK3 are commonly driven. The substrate 601 can also carry circuitry under the blocks BLK0, BLK1, BLK2, BLK3, along with one or more lower metal layers which are patterned in conductive paths to carry signals of the circuitry. The blocks BLK0, BLK1, BLK2, BLK3 are formed in an intermediate region 602 of the memory device. In an upper region 603 of the memory device, one or more upper metal layers are patterned in conductive paths to carry signals of the circuitry. Each block BLK0, BLK1, BLK2, BLK3 comprises a stacked area of memory cells, where alternating levels of the stack represent word lines. In one possible approach, each block BLK0, BLK1, BLK2, BLK3 has opposing tiered sides from which vertical contacts extend upward to an upper metal layer to form connections to conductive paths. While four blocks BLK0, BLK1, BLK2, BLK3 are illustrated as an example, two or more blocks can be used, extending in the x- and/or y-directions.

In one possible approach, the length of the plane, in the x-direction, represents a direction in which signal paths to word lines extend in the one or more upper metal layers (a word line or SGD line direction), and the width of the plane, in the y-direction, represents a direction in which signal paths to bit lines extend in the one or more upper metal layers (a bit line direction). The z-direction represents a height of the memory device.

FIG. 6B illustrates an example cross-sectional view of a portion of one of the blocks BLK0, BLK1, BLK2, BLK3 of FIG. 6A. The block comprises a stack 610 of alternating conductive and dielectric layers. In this example, the conductive layers comprise two SGD layers, two SGS layers and four dummy word line layers DWLD0, DWLD1, DWLS0 and DWLS1, in addition to data word line layers (word lines) WL0-WL111. The dielectric layers are labelled as DL0-DL116. Further, regions of the stack 610 which comprise NAND strings NS1 and NS2 are illustrated. Each NAND string encompasses a memory hole 618, 619 which is filled with materials which form memory cells adjacent to the word lines. A region 622 of the stack 610 is shown in greater detail in FIG. 6D and is discussed in further detail below. The dielectric layers can have variable thicknesses such that some of the conductive layers can be closer to or further from neighboring conductive layers. The thicknesses of the dielectric layers affect the “ON pitch,” which is a factor in memory density. Specifically, a smaller ON pitch allows for more memory cells in a given area but may compromise reliability.

The stack 610 includes a substrate 611, an insulating film 612 on the substrate 611, and a portion of a source line SL. NS1 has a source-end 613 at a bottom 614 of the stack and a drain-end 615 at a top 616 of the stack 610. Contact line connectors (e.g., slits, such as metal-filled slits) 617, 620 may be provided periodically across the stack 610 as interconnects which extend through the stack 610, such as to connect the source line to a particular contact line above the stack 610. The contact line connectors 617, 620 may be used during the formation of the word lines and subsequently filled with metal. A portion of a bit line BL0 is also illustrated. A conductive via 621 connects the drain-end 615 to BL0.

FIG. 6C illustrates a plot of memory hole diameter in the stack of FIG. 6B. The vertical axis is aligned with the stack of FIG. 6B and illustrates a width (wMH), e.g., diameter, of the memory holes 618 and 619. The word line layers WL0-WL111 of FIG. 6A are repeated as an example and are at respective heights z0-z111 in the stack. In such a memory device, the memory holes which are etched through the stack have a very high aspect ratio. For example, a depth-to-diameter ratio of about 25-30 is common. The memory holes may have a circular cross-section. Due to the etching process, the memory hole width can vary along the length of the hole. Typically, the diameter becomes progressively smaller from the top to the bottom of the memory hole. That is, the memory holes are tapered, narrowing at the bottom of the stack. In some cases, a slight narrowing occurs at the top of the hole near the select gate so that the diameter becomes slightly wider before becoming progressively smaller from the top to the bottom of the memory hole.

FIG. 6D illustrates a close-up view of the region 622 of the stack 610 of FIG. 6B. Memory cells are formed at the different levels of the stack at the intersection of a word line layer and a memory hole. In this example, SGD transistors 680, 681 are provided above dummy memory cells 682, 683 and a data memory cell MC. A number of layers can be deposited along the sidewall (SW) of the memory hole 630 and/or within each word line layer, e.g., using atomic layer deposition. For example, each column (e.g., the pillar which is formed by the materials within a memory hole 630) can include a charge-trapping layer or film 663 such as SiN or other nitride, a tunneling layer 664, a polysilicon body or channel 665, and a dielectric core 666. A word line layer can include a blocking oxide/block high-k material 660, a metal barrier 661, and a conductive metal such as Tungsten as a control gate. For example, control gates 690, 691, 692, 693, and 694 are provided. In this example, all of the layers except the metal are provided in the memory hole 630. In other approaches, some of the layers can be in the control gate layer. Additional pillars are similarly formed in the different memory holes. A pillar can form a columnar active area (AA) of a NAND string.

When a memory cell is programmed, electrons are stored in a portion of the charge-trapping layer which is associated with the memory cell. These electrons are drawn into the charge-trapping layer from the channel and through the tunneling layer. The threshold voltage Vt of a memory cell is increased in proportion to the amount of stored charge. During a sensing operation, the threshold voltage Vt is detected or measured. During an erase operation, the electrons return to the channel.

Each of the memory holes 630 can be filled with a plurality of annular layers comprising a blocking oxide layer, a charge trapping layer 663, a tunneling layer 664 and a channel layer. A core region of each of the memory holes 630 is filled with a body material, and the plurality of layers are between the core region and the word line layer in each of the memory holes 630. In some cases, the charge trapping layer 663 and the tunneling layer 664 are annular in shape. In other cases, as discussed in further detail below, these layers are semi-circular in shape.

The NAND string can be considered to have a floating body channel because the length of the channel is not formed on a substrate. Further, the NAND string is provided by a plurality of word line layers above one another in a stack and separated from one another by dielectric layers.

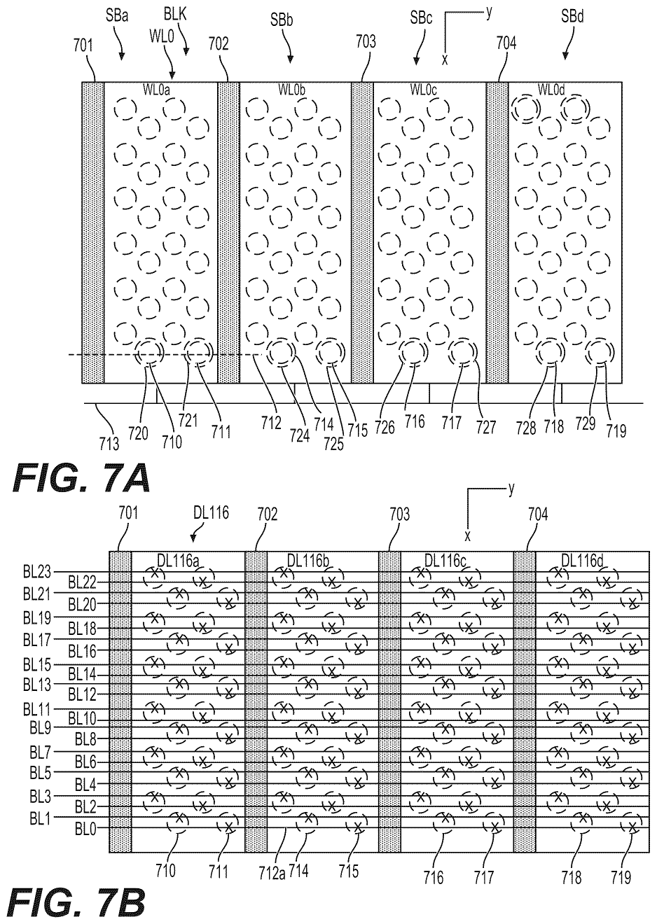

FIG. 7A illustrates a top view of an example word line layer WL0 of the stack 610 of FIG. 6B. As mentioned, a three-dimensional memory device can comprise a stack of alternating conductive and dielectric layers. The conductive layers provide the control gates of the SG transistors and memory cells. The layers used for the SG transistors are SG layers and the layers used for the memory cells are word line layers. Further, memory holes are formed in the stack and filled with a charge-trapping material and a channel material. As a result, a vertical NAND string is formed. Source lines are connected to the NAND strings below the stack and bit lines are connected to the NAND strings above the stack.

A block BLK in a three-dimensional memory device can be divided into sub-blocks, where each sub-block comprises a NAND string group which has a common SGD control line. Further, a word line layer in a block can be divided into regions. Each region is in a respective sub-block and can extend between contact line connectors (e.g., slits) which are formed periodically in the stack to process the word line layers during the fabrication process of the memory device. This processing can include replacing a sacrificial material of the word line layers with metal. Generally, the distance between contact line connectors should be relatively small to account for a limit in the distance that an etchant can travel laterally to remove the sacrificial material, and that the metal can travel to fill a void which is created by the removal of the sacrificial material. For example, the distance between contact line connectors may allow for a few rows of memory holes between adjacent contact line connectors. The layout of the memory holes and contact line connectors should also account for a limit in the number of bit lines which can extend across the region while each bit line is connected to a different memory cell. After processing the word line layers, the contact line connectors can optionally be filed with metal to provide an interconnect through the stack.

In this example, there are four rows of memory holes between adjacent contact line connectors. A row here is a group of memory holes which are aligned in the x-direction. Moreover, the rows of memory holes are in a staggered pattern to increase the density of the memory holes. The word line layer or word line is divided into regions WL0a, WL0b, WL0c and WL0d which are each connected by a contact line 713. The last region of a word line layer in a block can be connected to a first region of a word line layer in a next block, in one approach. The contact line 713, in turn, is connected to a voltage driver for the word line layer. The region WL0a has example memory holes 710, 711 along a contact line 712. The region WL0b has example memory holes 714, 715. The region WL0c has example memory holes 716, 717. The region WL0d has example memory holes 718, 719. The memory holes are also shown in FIG. 7B. Each memory hole can be part of a respective NAND string. For example, the memory holes 710, 714, 716 and 718 can be part of NAND strings NS0_SBa, NS1_SBb, NS2_SBc, NS3_SBd, and NS4_SBe, respectively.

Each circle represents the cross-section of a memory hole at a word line layer or SG layer. Example circles shown with dashed lines represent memory cells which are provided by the materials in the memory hole and by the adjacent word line layer. For example, memory cells 720, 721 are in WL0a, memory cells 724, 725 are in WL0b, memory cells 726, 727 are in WL0c, and memory cells 728, 729 are in WL0d. These memory cells are at a common height in the stack.

Contact line connectors (e.g., slits, such as metal-filled slits) 701, 702, 703, 704 may be located between and adjacent to the edges of the regions WL0a-WL0d. The contact line connectors 701, 702, 703, 704 provide a conductive path from the bottom of the stack to the top of the stack. For example, a source line at the bottom of the stack may be connected to a conductive line above the stack, where the conductive line is connected to a voltage driver in a peripheral region of the memory device.

FIG. 7B illustrates a top view of an example top dielectric layer DL116 of the stack of FIG. 6B. The dielectric layer is divided into regions DL116a, DL116b, DL116c and DL116d. Each region can be connected to a respective voltage driver. This allows a set of memory cells in one region of a word line layer being programmed concurrently, with each memory cell being in a respective NAND string which is connected to a respective bit line. A voltage can be set on each bit line during each programming, sensing, or erasing operation.

The region DL116a has the example memory holes 710, 711 along a contact line 712, which is coincident with a bit line BL0. A number of bit lines extend above the memory holes and are connected to the memory holes as indicated by the “X” symbols. BL0 is connected to a set of memory holes which includes the memory holes 711, 715, 717, 719. Another example bit line BL1 is connected to a set of memory holes which includes the memory holes 710, 714, 716, 718. The contact line connectors (e.g., slits, such as metal-filled slits) 701, 702, 703, 704 from FIG. 7A are also illustrated, as they extend vertically through the stack. The bit lines can be numbered in a sequence BL0-BL23 across the DL116 layer in the x-direction.

Different subsets of bit lines are connected to memory cells in different rows. For example, BL0, BL4, BL8, BL12, BL16, BL20 are connected to memory cells in a first row of cells at the right-hand edge of each region. BL2, BL6, BL10, BL14, BL18, BL22 are connected to memory cells in an adjacent row of cells, adjacent to the first row at the right-hand edge. BL3, BL7, BL11, BL15, BL19, BL23 are connected to memory cells in a first row of cells at the left-hand edge of each region. BL1, BL5, BL9, BL13, BL17, BL21 are connected to memory cells in an adjacent row of memory cells, adjacent to the first row at the left-hand edge.

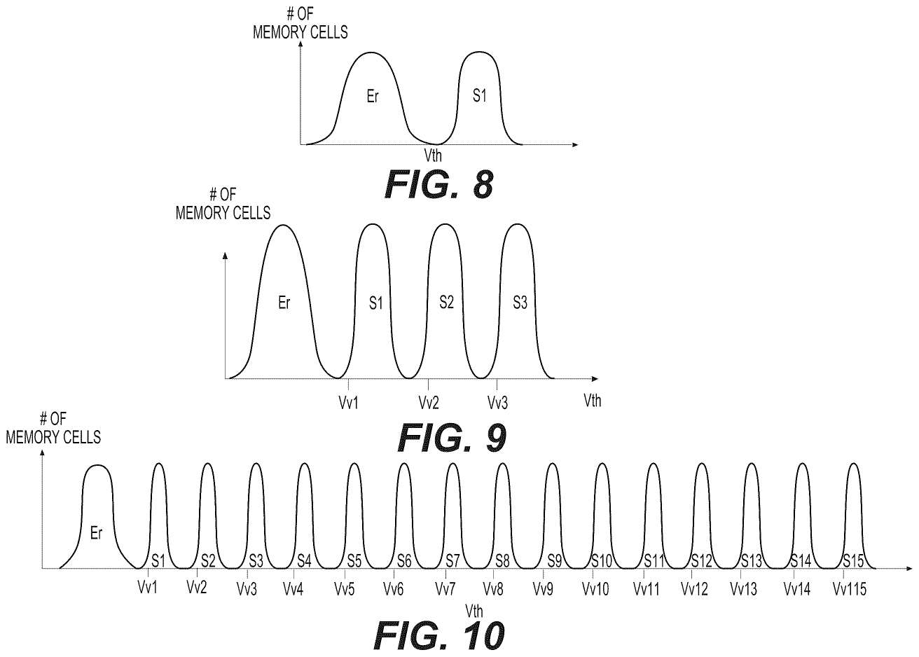

The memory cells of the memory blocks can be programmed to store one or more bits of data in multiple data states, each of which is associated with a respective threshold voltage Vt range. For example, FIG. 8 depicts a threshold voltage Vt distribution of a group of memory cells programmed according to a one bit per memory cell (SLC) storage scheme. In the SLC storage scheme, there are two total data states, including the erased state (Er) and a single programmed data state (S1). FIG. 9 illustrates the threshold voltage Vt distribution of a two bits per cell (MLC) storage scheme that includes four total data states, namely the erased state (Er) and three programmed data states (S1, S2, and S3). Each programmed data state (S1-S3) is associated with a respective verify voltage (Vv1-Vv3), which is employed during a verify portion of a programming operation as discussed in further detail below. FIG. 10 depicts a threshold voltage Vt distribution of a four bits per cell (QLC) storage scheme that includes sixteen total data states, namely the erased state (Er) and fifteen programmed data states (S1-S15). Other storage schemes are also available, such as three bits per cell (TLC) with eight data states or five bits per cell (PLC) with thirty-two data states.

A sensing operation (verify or read) begins with a sense node SEN on the drain side of the memory block being charged to a predetermined charged voltage. Simultaneously, all of the memory cells of a selected NAND string except a selected memory cell are turned on by a pass voltage VREAD. A reference voltage VCG (e.g., any of Vv1-Vv15 depicted in FIG. 10, depending on which data state is being verified) is applied to a control gate of a selected word line WLn that contains the selected memory cell. The sense node SEN is then discharged through the NAND string. Since all of the memory cells except the selected memory cell are turned on by the elevated pass voltage VREAD, the discharge current Icell through the NAND string is largely dictated by whether the reference voltage VCG does or does not turn on the selected memory cell, i.e., whether the threshold voltage Vt of the selected memory cell is below or above the reference voltage VCG.

At a discharge time T_sense, a voltage on the SEN node is sensed by the sensing circuitry and compared to V_sense, which is the threshold voltage Vt of a ΔVPGM sensing transistor. If the threshold voltage Vt of the selected memory cell is higher than the reference voltage VCG, then the selected memory cell was not turned on by the reference voltage VCG and conducts a very small/negligible current resulting in only a small discharge of SEN node voltage. Thus, the SEN node voltage will remain higher than V_sense. On the other hand, if the threshold voltage Vt of the selected memory cell is lower than the reference voltage VCG, then the reference voltage VCG will turn on the selected memory cell and a larger discharging current will result in the SEN node having a lower voltage than V_sense. This process is performed for each memory cell of the selected word line WLn and can be repeated at different reference voltages to read the data stored in the memory cells of the selected word line WLn.

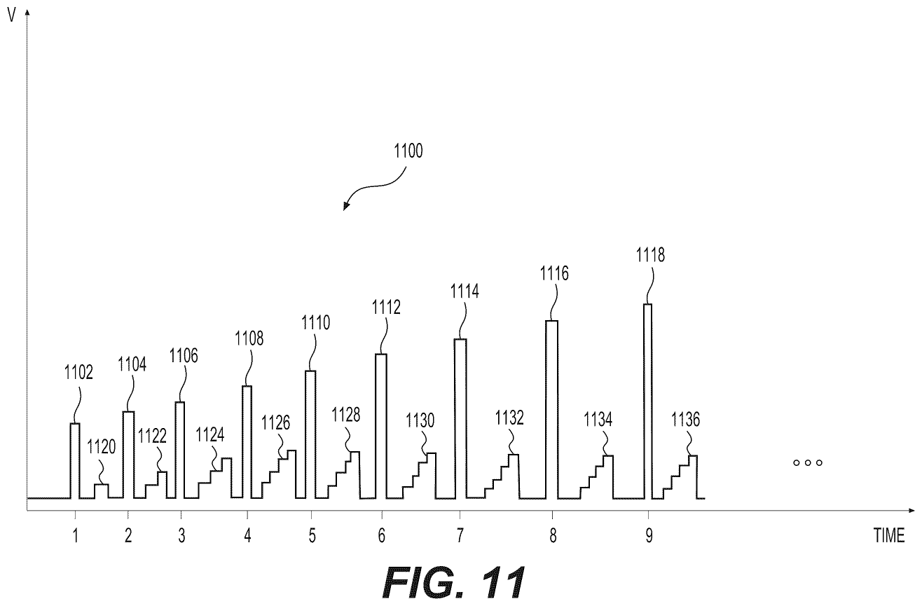

Programming to multiple bits per memory cell (for example, MLC, TLC, or QLC) typically includes a plurality of program loops. FIG. 11 depicts a waveform 1100 of the voltages applied to a selected word line during an example memory cell programming operation for programming the memory cells of the selected word line to a greater number of bits per memory cell (e.g., TLC or QLC). As depicted, each program loop includes a programming pulse (“VPGM pulse”) 1102-1118 at a programming voltage VPGM and one or more verify pulses 1120-1136, depending on which data states are being programmed in a particular program loop. A square waveform is depicted for each pulse for simplicity; however, other shapes are possible, such as a multilevel shape or a ramped shape.

Incremental Step Pulse Programming (ISPP) is used in this example pulse train, which means that the VPGM pulse amplitude steps up, or increases, in each successive program loop. In other words, the pulse train includes VPGM pulses that increase stepwise in amplitude with each successive program loop by a fixed step size (dVPGM). A new pulse train starts with an initial VPGM pulse level VPGMU and ends at a final VPGM pulse level, which does not exceed a maximum allowed level. The example pulse train 1100 includes a series of VPGM pulses 1102-1118 that are applied to a selected word line that includes a set of non-volatile memory cells. One or more verify voltage pulses 1120-1136 are provided after each VPGM pulse as an example, based on the target data states which are being verified in the program loop. The verify voltages may correspond with voltages Vv1-Vv3 shown in FIG. 9 or Vv1-Vv15 shown in FIG. 10 or another set of verify voltages, depending on the requirements of a particular programming pass. Concurrent with the application of the verify pulses, a sensing operation can determine whether a particular memory cell in the selected word line has a threshold voltage Vt above the verify voltage associated with its intended data state. If a selected memory cell is determined to have a threshold voltage Vt above the verify voltage it is being programmed to, then that memory cell is said to have passed verify. When a memory cell passes verify, programming of that memory cell is completed and further programming of that memory cell is inhibited for all remaining program loops by applying an inhibit voltage to a bit line that is coupled with the memory cell concurrent with subsequent VPGM pulses. Programming proceeds until all or a significant number of memory cells pass verify, in which case, programming passes, or until a predetermined maximum number of program loops is exceeded, in which case, programming fails. In some embodiments, the memory cells of a word line can be divided into a series of string groups, or simply strings, that can be programmed independently of one another, and programming can commence from one string to another across the word line before proceeding to the next word line in the memory block.

Programming of the memory cells of a selected word line can be conducted in either a full sequence programming operation or a multi-pass programming operation. In a full sequence programming operation, the memory cells are programmed directly to their intended data states in a single programming pass, e.g., the programming pass depicted in FIG. 11. In a multi-pass programming operation, the memory cells are programmed to their final programmed data states in two or more programming passes or stages, e.g., a first (sometimes known as “foggy”) pass and a second (sometimes known as “fine”) pass. The pulse train of each of these programming passes may resemble the programming pass depicted in FIG. 11, but a different, lesser set of verify voltages may be employed during the foggy pass.

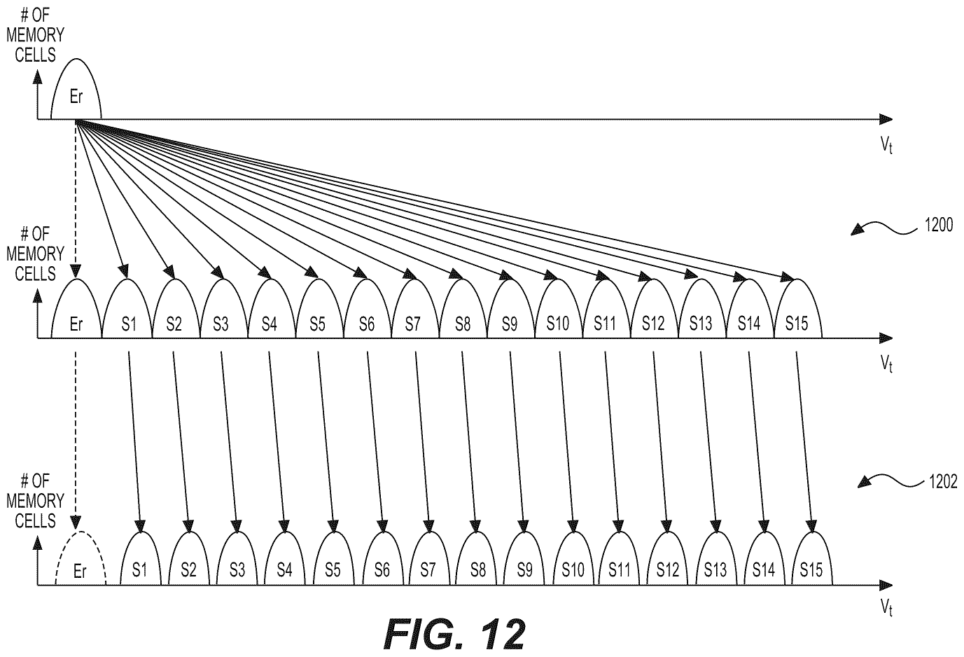

One example of a multi-pass programming operation to program the memory cells to QLC is schematically depicted in FIG. 12. In the first (foggy) pass 1200, the memory cells are programmed quickly (with a high step size dVPGM) to approximately all of data states S1-S15, but each data state has a large or “fat” threshold voltage Vt distribution and the distribution curves may overlap with one another. In the second (fine) pass 1202, the memory cells are programmed more slowly (with a smaller step size dVPGM) and with higher accuracy to tighten the threshold voltage Vt distributions and improve the reliability of the data. In some known multi-pass programming operations, the foggy data may be unreadable due to large overlaps in the threshold voltage Vt distribution curves of the various data states.

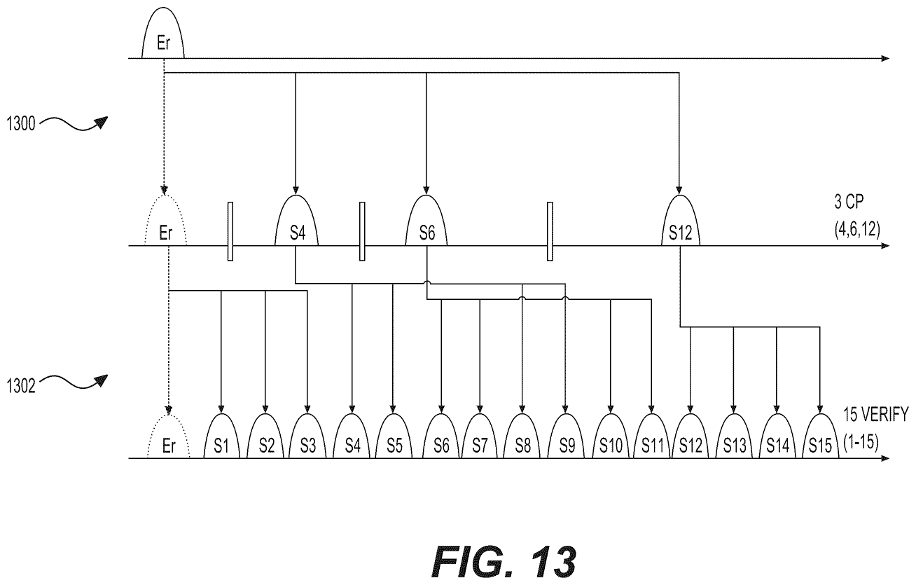

Another type of multi-pass programming operation, which is sometimes referred to as “MLC-Fine,” is schematically depicted in FIG. 13. In a first pass 1300, rather than programming the memory cells to approximately all of the programmed data states S1-S15, the memory cells are programmed only to a plurality of checkpoint data states, e.g., the S4, S6, and S12 data states in this example. A relatively large voltage step size dVPGM may be used in the first pass. In a second pass 1302, the memory cells in the Er state are either left in the erased state (Er) or are programmed to the S1, S2, or S3 data states; the memory cells in the S4 data state are either left in the S4 data state or are programmed to the S5, S10, or S11 data states; the memory cells in the S6 data state are either left in the S6 data state or programmed to the S7, S10, or S11 data states; and the memory cells of the S12 data state are either left in the S12 data state or are programmed to the S13, S14, or S15 data states. In some embodiments, the first and second passes may take different forms. For example, the memory cells could be programmed to different or more checkpoint data states in the first pass than the S4, S6, and S12 data states.

In some embodiments, in order to protect data from a problem sometimes referred to as neighboring wordline interference (NWI), programming according to a multi-pass programming technique does not involve performing the second pass immediately after the first pass is completed. Instead, the programming order includes performing the first pass on a specific word line WLn, followed by the first pass on a subsequent word line WLn+1, and then performing the second pass on the specific word line WLn. For example, the programming order could follow the following order: WLn (first pass), WLn+1 (first pass), WLn (second pass), WLn+2 (first pass), WLn+1 (second pass), WLn+3 (first pass), WLn+2 (second pass), and so on.

Foggy-fine techniques generally offer better performance than MLC-fine techniques, yet foggy-fine techniques present certain challenges. For instance, according to many known foggy-fine techniques, the foggy data (1200 in FIG. 12) written to a selected word line WLn is not readable after only the foggy pass. Thus, according to some known foggy-fine techniques, four pages of user data for the word line WLn are stored in system cache (off-die) until the fine pass is completed. In an example, one known type of foggy-fine programming technique requires 1,792 kB of system cache. The foggy-fine approach also requires the transmission of four pages of data (16 data states) from the system/host to the die before each foggy pass and again before each fine pass. Consequently, for each word line to undergo both the foggy and fine passes, these four pages of data need to be transmitted from the system cache to the die twice. In addition to requiring system resources, this frequent transmission of data from the system cache to the memory device also consumes a significant amount of power.

Although performance of MLC-fine programming is typically lower as compared to foggy-fine programming, MLC-fine programming offers a significant advantage in terms of system memory usage. This is due to the fact that the data (1300 in FIG. 13) programmed into the word line WLn during the MLC pass is readable. Consequently, at the onset of the fine pass for a word line WLn, two pages of data can be retrieved from the word line WLn in an internal data load (IDL) read operation, and only two pages of data have to be retrieved from the system cache. Thus, MLC-fine programming is more efficient than foggy-fine programming from a memory-efficiency standpoint.

One aspect of the present disclosure is related to a multi-pass programming technique that offers improved performance (comparable to foggy-fine programming) at an improved memory-efficiency (even better than MLC-fine). According to these techniques, during the first (“foggy”) pass, two pages out of four pages of user data are programmed as foggy data into the selected word line. Either before or after the first (“foggy”) pass, the other two pages of user data are programmed as parity data into one or two memory blocks (specifically, one or more parity blocks) of a same plane as a selected memory block being programmed. Prior to the fine pass, the four pages of user data can be reconstructed by reading the foggy data in the selected wordl ine and reading the parity data in the parity blocks. Thus, unlike the foggy-fine programming techniques discussed above, according to the techniques of the present disclosure, minimal system cache is required and the four pages of user data only has to be transmitted to the memory device once (before the foggy pass). In other words, these techniques allow the four pages of user data to be directly read from the foggy and parity data that are stored on-chip without any decoding operation as is found in some other processes that do not rely on system cache.

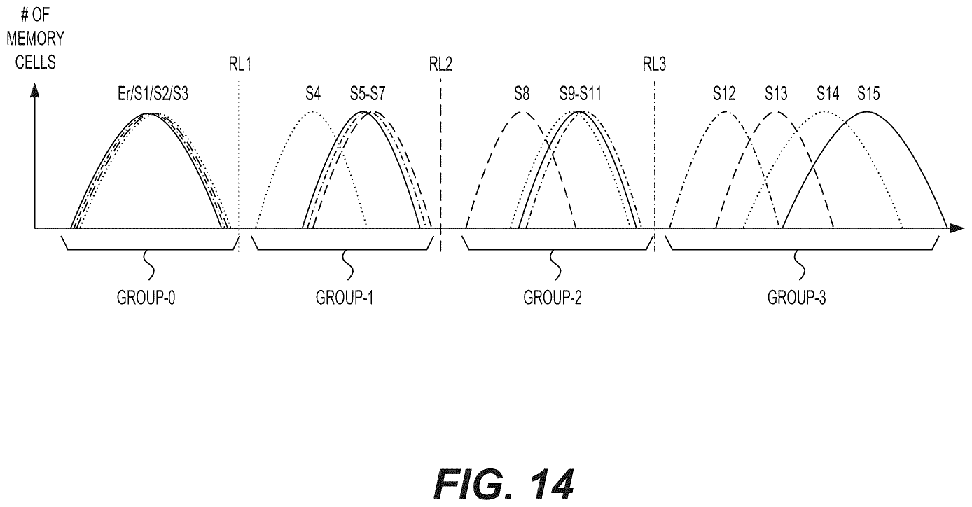

Turning now to FIG. 14, during a first (foggy) pass, the memory cells of a selected word line are programmed using four checkpoint data states (S4, S8, and S12 in this example) to an MLC-like distribution. This MLC-like distribution includes four groups of memory cells, each of which is associated with a threshold voltage Vt range and contains the memory cells that are ultimately being programmed to four data states. For example, in this example, Group_0 includes the memory cells remaining in the erased data state Er and the memory cells being programmed to the S1-S3 data states; Group_1 includes the memory cells being programmed to the S4-S7 data states; Group_2 includes the memory cells being programmed to the S8-S11 data states; and Group_3 includes the memory cells being programmed to the S12-S15 data states. There is a large threshold voltage Vt margin between the groups so that, during an IDL read operation prior to the fine pass, the memory device can determine which groups the memory cells are in with a high degree of accuracy. Three IDL read levels RL1, RL2, and RL3 (or reference voltages for the IDL read operation) are set at voltages in the voltage gaps between the four groups.

As illustrated, the threshold voltage Vt distributions of the memory cells within Group_1 and Group_2 can be spread out, or expanded, using one or more “dummy pulses” (program loops that include programming pulses but no verify operations) following the S4 and S8 data states respectively passing verify. However, the threshold voltage Vt margin between the S7 and S8 data states and the threshold voltage Vt margin between the S11 and S12 data states must be maintained at a relatively high level such that there is little or no overlap in the threshold voltages Vt between the different groups. For Group_3, which only includes memory cells with threshold voltages Vt above the read level RL3, the memory cells being programmed to the S13, S14, and S15 data states can be programmed further with in increasing number of dummy pulses to spread out these threshold voltage Vt distributions and make programming quicker during the ensuing second (fine) programming pass. The dummy pulses are discussed in further detail below.

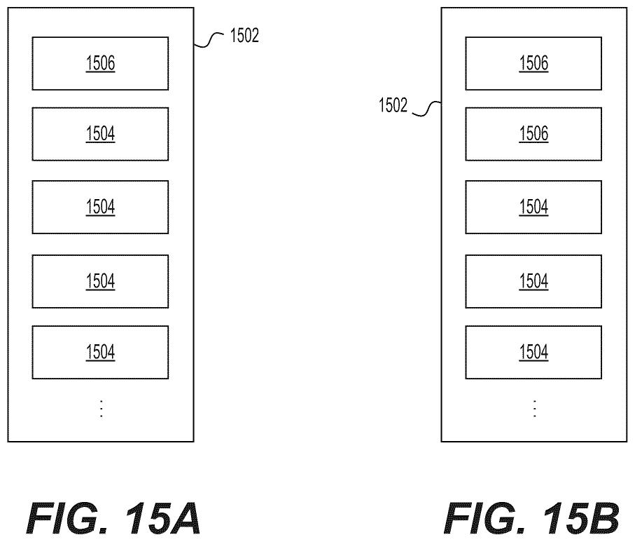

Turning now to FIGS. 15A and 15B, the parity data is programmed either in MLC format (see FIG. 9 for an example MLC threshold voltage Vt distribution) into a dedicated parity block 1506 (illustrated in FIG. 15A and sometimes referred to as “MLC cache”) or is programmed in SLC format (see FIG. 8 for an example SLC threshold voltage Vt distribution) into two parity blocks 1506 (illustrated in FIG. 15B and sometimes referred to as “SLC cache”). The other blocks 1504 in the plane 1502 are data blocks that are configured to store user data in the QLC format.

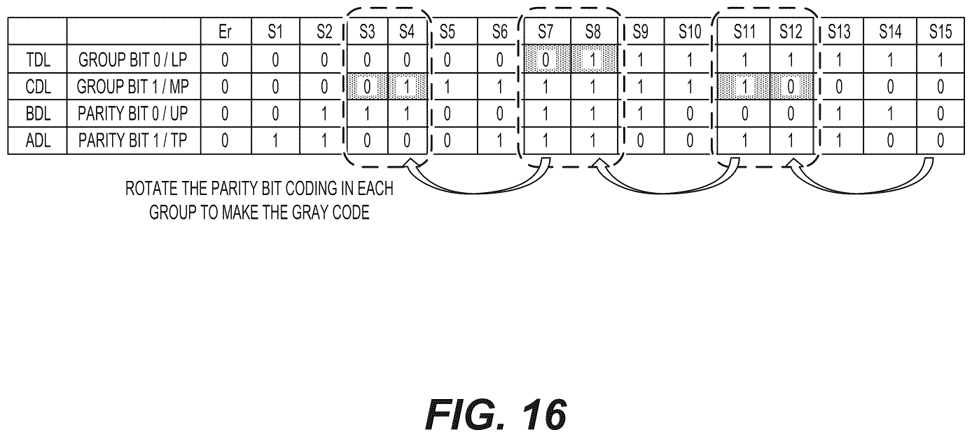

Referring to FIG. 16, according to the exemplary embodiment, at the beginning of the second (fine) programming pass, the four pages of user data of each memory cell in the selected word line can be retrieved from the foggy data in the selected word line and the parity data in the parity blocks using a “1-2-6-6” coding scheme. This process involves first performing an IDL read operation on the foggy data (depicted in FIG. 14) using the three IDL read levels RL1-RL3 two retrieve two of the four pages of user data. In other words, these two pages of the user data are read from the foggy data without any decoding operation. In this example embodiment, the IDL read operation retrieves the lower page and a middle page of the user data from the foggy data. The lower page of data is read by performing the sensing operation using RL2 as the reference voltage. For each memory cell of the selected word line, if the threshold voltage Vt is below RL2, then that memory cell is being programmed to one of the ER-S7 data states and the lower page bit is “0.” On the other hand, if the threshold voltage Vt is above RL2, then that memory cell is being programmed to one of the S8-S15 data states and the lower page bit is “1.” Thus, in this embodiment, the lower page can be decoded using only a single sensing operation that includes a reference voltage at the IDL read level RL2.

The middle page of the user data can be read using two sensing operations with reference voltages at the IDL read levels RL1 and RL3. In this example, if a memory cell has a threshold voltage Vt below RL1 or above RL3, then its middle page bit is “0,” and if a memory cell has a threshold voltage Vt between RL1 and RL3, then its middle page bit is “1.” Thus, in this embodiment, the middle page can be read using only two sensing operations.

The upper and top pages of user data are retrieved from the parity bits by performing a sensing operation on the one (if the parity bits are stored in MLC format) or two (if the parity bits are stored in SLC format) parity blocks. In other words, the parity bits actually store two pages of user data, which is different from some other known processes where the parity bits do not contain user data but rather contain data that can be used to decode the foggy data and thereby establish what the user data is.

Accordingly, by reading the foggy data and the parity data, all four pages of the user data can be read on-chip without retrieving any of these pages from the system cache and without any decoding operation. The four pages of user data can then be programmed into the selected word line from the foggy data in the second (fine) programming pass so that the user data is stored in the QLC storage format depicted in FIG. 10. During the fine pass, the memory cells of the erased data state Er remain in the erased data state; the memory cells of the S1 data state are programmed Group_0 using the verify voltage Vv1 (illustrated in FIG. 10); the memory cells of the S2 data state are programmed from Group_0 using the verify voltage Vv2; the memory cells of the S3 data state are programmed from Group_0 using the verify voltage Vv3; the memory cells of the S4 data state are programmed from Group_1 using the verify voltage Vv4; the memory cells of the S5 data state are programmed from Group_1 using the verify voltage Vv5; the memory cells of the S6 data state are programmed from Group_1 using the verify voltage Vv6; the memory cells of the S7 data state are programmed from Group_1 using the verify voltage Vv7; the memory cells of the S8 data state are programmed from Group_2 using the verify voltage Vv8; the memory cells of the S9 data state are programmed from Group_2 using the verify voltage Vv9; the memory cells of the S10 data state are programmed from Group_2 using the verify voltage Vv10; the memory cells of the S11 data state are programmed from Group_2 using the verify voltage Vv11; the memory cells of the S12 data state are programmed from Group_3 using the verify voltage Vv12; the memory cells of the S13 data state are programmed from Group_3 using the verify voltage Vv13; the memory cells of the S14 data state are programmed from Group_3 using the verify voltage Vv14; and the memory cells of the S15 data state are programmed from Group_3 using the verify voltage Vv15.

Turning back to FIG. 14, in the exemplary embodiment, during the foggy pass, the threshold voltage Vt distributions of the memory cells in Group_1, Group_2, and Group_3 can be expanded to improve programming performance during the following fine pass while still allowing for adequate margin between the groups to allow the two pages of user data to be read from the foggy data during the IDL read. One way to expand the threshold voltate Vt distributions in these groups is with the use of dummy pulses. In the exemplary embodiment, following the checkpoint S4 data state passing verify, the memory cells being programmed to the S5, S6, and S7 data states all receive one additional dummy pulse while the memory cells being programmed to the S4 data state are inhibited to prevent overprogramming. Following the checkpoint S8 data state passing verify, the memory cells being programmed to the S9, S10, and S11 data states all receive one additional dummy pulse while the memory cells being programmed to the S8 data state are inhibited to prevent overprogramming. The threshold voltages Vt memory cells in Group_3 can be more spread out because there is no margin above the S15 data state to worry about. In this example, following the checkpoint S12 data state passing verify, the S12 memory cells are inhibited from further programming loops; the S13 memory cells receive one dummy pulse and then are inhibited; the S14 memory cells receive two dummy pulses and then are inhibited; and the S15 memory cells receive three dummy pulses.

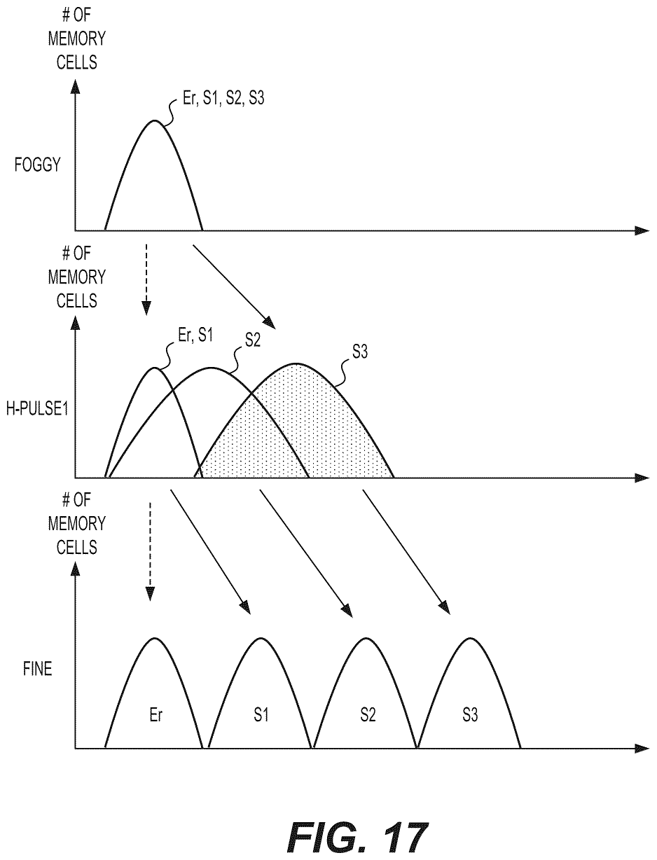

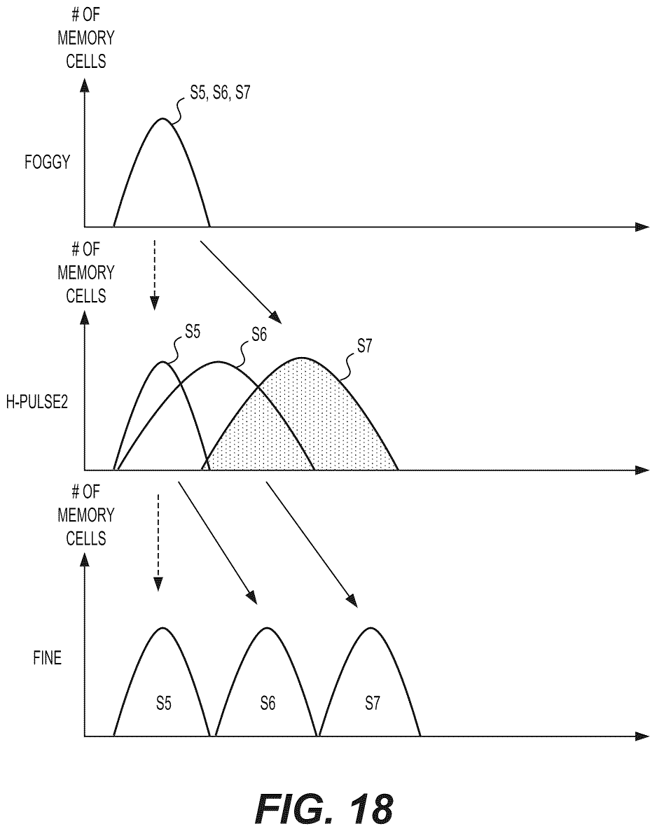

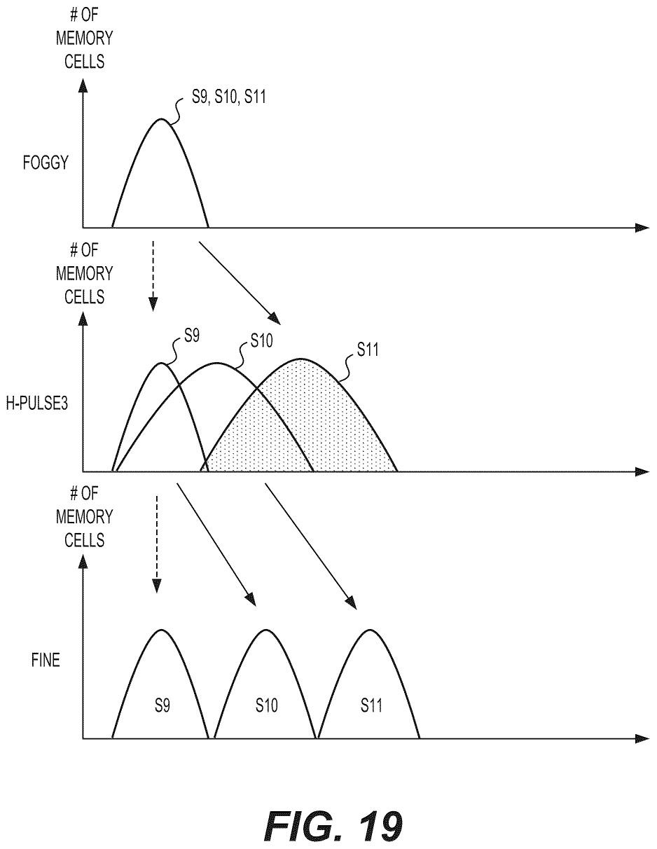

Turning now to FIGS. 17-19, in some embodiments, the threshold voltages Vt of the memory cells in Group_0, Group_1, and Group_2 can be further spread out after the IDL read operation is completed and immediately prior to the fine pass with a series of so-called “H-Pulses.” Specifically, the threshold voltages Vt of the memory cells of Group_0 are separated in a first H-Pulse, the memory cells of Group_1 are separated in a second H-Pulse, and the memory cells of Group_2 are separated in a thid H-Pulse.

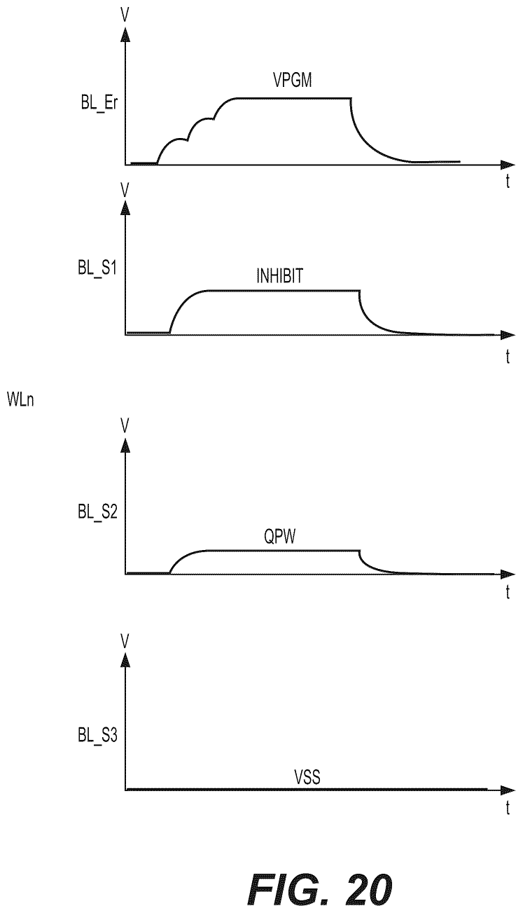

During the first H-Pulse, a VPGM pulse is applied to the selected word line WLn. Concurrent with the VPGM pulse, the bit lines that are coupled with the memory cells being programmed to the erased data state Er and the S1, S2, and S3 data states all receive different voltages. Specifically, as illustrated in FIG. 20, the bit lines (BL_Er) that are electrically connected with the erased data state Er memory cells and the bit lines (BL_S1) that are coupled to the S1 memory cells receive an inhibit voltage so that the threshold voltages Vt of these memory cells do not rise during the first H-Pulse. The bit lines (BL_S2) that are coupled to the S2 memory cells receive a quick pass write QPW voltage, which is less than the inhibit voltage, to allow for moderate programming of the S2 memory cells during the H-Pulse. The bit lines (BL_S3) that are coupled to the S3 memory cells receive a very low voltage VSS to allow for fast programming of the S3 memory cells during the H-Pulse. Turning back to FIG. 17, the H-Pulse allows the threshold voltages Vt of the memory cells being programmed to the S2 and S3 data states to be very quickly and efficiently raised closer to the verify voltages Vv2, Vv3 respectively. During the fine pulse, the S1, S2, and S3 memory cells are programmed to their respective data states using the verify voltages Vv1, Vv2, and Vv3 (illustrated in FIG. 10) respectively.

During the second H-Pulse, a VPGM pulse (at a higher voltage than the first H-Pulse) is applied to the selected word line WLn. Concurrent with the VPGM pulse, the bit lines that are coupled with the S5 memory cells receive the inhibit voltage to inhibit programming, the bit lines that are coupled with the S6 memory cells receive the QPW voltage to allow for moderate programming, and the bit lines that are coupled with the S7 memory cells receive the very low VSS voltage to allow for fast programming. During the fine pass, the S4, S5, S6, and S7 memory cells are programmed to the S4, S5, S6, and S7 data states using the verify voltages Vv4, Vv5, Vv6, and Vv7 (illustrated in FIG. 10) respectively.

During the third H-Pulse, a VPGM pulse (at a higher voltage than the second H-Pulse) is applied to the selected word line WLn. Concurrent with the VPGM pulse, the bit lines that are coupled with the S9 memory cells receive the inhibit voltage to inhibit programming, the bit lines that are coupled with the S10 memory cells receive the QPW voltage to allow for moderate programming, and the bit lines that are coupled with the S11 memory cells receive the very low VSS voltage to allow for fast programming. During the fine pass, the S8, S9, S10, and S11 memory cells are programmed to the S8, S9, S10, and S11 data states respectively using the verify voltages Vv8, Vv9, Vv10, and Vv11 (illustrated in FIG. 10) respectively.

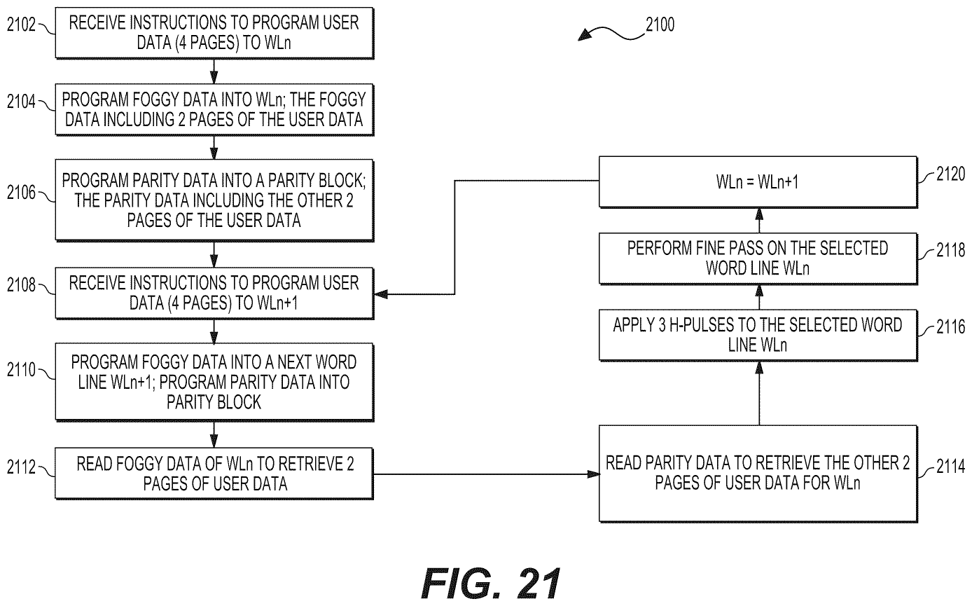

FIG. 21 is a flow chart 2100 depicting the steps of programming the memory cells of a selected word line according to an exemplary embodiment of the present disclosure. These steps could be performed by the controller; a processor or processing device or any other circuitry, executing instructions stored in memory; and/or other circuitry described herein that is specifically configured/programmed to execute the following steps.

At step 2102, instructions are received at the memory device to program four pages of user data to a selected word line WLn. At step 2104, the process continues with performing a foggy pass on the selected word line WLn to program foggy data into the selected word line WLn, the foggy data including two pages of the user data. At step 2106, two pages of parity data are programmed into one or two parity blocks. The parity data includes the other two pages of user data.

At step 2108, the memory device receives four pages of user data to be programmed to a next sequential word line WLn+1. At step 2110, the foggy pass is performed on the next word line WLn+1 its memory cells to include foggy data, which includes two bits of the user data. Also at this step, the two pages of parity data are programmed into the parity block or parity blocks. The parity data includes the other two pages of user data.

At step 2112, the foggy data of the selected word line WLn is read to retrieve the first two pages of user data for the selected word line WLn. At step 2114, the parity data is read to retrtieve the other two pages of user data for the selected word line WLn.

At step 2116, three H-pulses are applied to the selected word line WLn to distribute the threshold voltages of the memory cells in the selected word line WLn. At step 2118, the fine pass is performed on the selected word line WLn to program the memory cells of the selected word line WLn to their final data states. At step 2120, the selected word line WLn is incrementally advanced, e.g., WLn =WLn+1. Following step 2120, the process returns to step 2108.

Various terms are used herein to refer to particular system components. Different companies may refer to a same or similar component by different names and this description does not intend to distinguish between components that differ in name but not in function. To the extent that various functional units described in the following disclosure are referred to as “modules,” such a characterization is intended to not unduly restrict the range of potential implementation mechanisms. For example, a “module” could be implemented as a hardware circuit that includes customized very-large-scale integration (VLSI) circuits or gate arrays, or off-the-shelf semiconductors that include logic chips, transistors, or other discrete components. In a further example, a module may also be implemented in a programmable hardware device such as a field programmable gate array (FPGA), programmable array logic, a programmable logic device, or the like. Furthermore, a module may also, at least in part, be implemented by software executed by various types of processors. For example, a module may comprise a segment of executable code constituting one or more physical or logical blocks of computer instructions that translate into an object, process, or function. Also, it is not required that the executable portions of such a module be physically located together, but rather, may comprise disparate instructions that are stored in different locations and which, when executed together, comprise the identified module and achieve the stated purpose of that module. The executable code may comprise just a single instruction or a set of multiple instructions, as well as be distributed over different code segments, or among different programs, or across several memory devices, etc. In a software, or partial software, module implementation, the software portions may be stored on one or more computer-readable and/or executable storage media that include, but are not limited to, an electronic, magnetic, optical, electromagnetic, infrared, or semiconductor-based system, apparatus, or device, or any suitable combination thereof. In general, for purposes of the present disclosure, a computer-readable and/or executable storage medium may be comprised of any tangible and/or non-transitory medium that is capable of containing and/or storing a program for use by or in connection with an instruction execution system, apparatus, processor, or device.

Similarly, for the purposes of the present disclosure, the term “component” may be comprised of any tangible, physical, and non-transitory device. For example, a component may be in the form of a hardware logic circuit that is comprised of customized VLSI circuits, gate arrays, or other integrated circuits, or is comprised of off-the-shelf semiconductors that include logic chips, transistors, or other discrete components, or any other suitable mechanical and/or electronic devices. In addition, a component could also be implemented in programmable hardware devices such as field programmable gate arrays (FPGA), programmable array logic, programmable logic devices, etc. Furthermore, a component may be comprised of one or more silicon-based integrated circuit devices, such as chips, die, die planes, and packages, or other discrete electrical devices, in an electrical communication configuration with one or more other components via electrical conductors of, for example, a printed circuit board (PCB) or the like. Accordingly, a module, as defined above, may in certain embodiments, be embodied by or implemented as a component and, in some instances, the terms module and component may be used interchangeably.

Where the term “circuit” is used herein, it includes one or more electrical and/or electronic components that constitute one or more conductive pathways that allow for electrical current to flow. A circuit may be in the form of a closed-loop configuration or an open-loop configuration. In a closed-loop configuration, the circuit components may provide a return pathway for the electrical current. By contrast, in an open-looped configuration, the circuit components therein may still be regarded as forming a circuit despite not including a return pathway for the electrical current. For example, an integrated circuit is referred to as a circuit irrespective of whether the integrated circuit is coupled to ground (as a return pathway for the electrical current) or not. In certain exemplary embodiments, a circuit may comprise a set of integrated circuits, a sole integrated circuit, or a portion of an integrated circuit. For example, a circuit may include customized VLSI circuits, gate arrays, logic circuits, and/or other forms of integrated circuits, as well as may include off-the-shelf semiconductors such as logic chips, transistors, or other discrete devices. In a further example, a circuit may comprise one or more silicon-based integrated circuit devices, such as chips, die, die planes, and packages, or other discrete electrical devices, in an electrical communication configuration with one or more other components via electrical conductors of, for example, a printed circuit board (PCB). A circuit could also be implemented as a synthesized circuit with respect to a programmable hardware device such as a field programmable gate array (FPGA), programmable array logic, and/or programmable logic devices, etc. In other exemplary embodiments, a circuit may comprise a network of non-integrated electrical and/or electronic components (with or without integrated circuit devices). Accordingly, a module, as defined above, may in certain embodiments, be embodied by or implemented as a circuit.

It will be appreciated that example embodiments that are disclosed herein may be comprised of one or more microprocessors and particular stored computer program instructions that control the one or more microprocessors to implement, in conjunction with certain non-processor circuits and other elements, some, most, or all of the functions disclosed herein. Alternatively, some or all functions could be implemented by a state machine that has no stored program instructions, or in one or more application-specific integrated circuits (ASICs) or field-programmable gate arrays (FPGAs), in which each function or some combinations of certain of the functions are implemented as custom logic. A combination of these approaches may also be used. Further, references below to a “controller” shall be defined as comprising individual circuit components, an application-specific integrated circuit (ASIC), a microcontroller with controlling software, a digital signal processor (DSP), a field programmable gate array (FPGA), and/or a processor with controlling software, or combinations thereof.

Additionally, the terms “couple,” “coupled,” or “couples,” where may be used herein, are intended to mean either a direct or an indirect connection. Thus, if a first device couples, or is coupled to, a second device, that connection may be by way of a direct connection or through an indirect connection via other devices (or components) and connections.

Regarding, the use herein of terms such as “an embodiment,” “one embodiment,” an “exemplary embodiment,” a “particular embodiment,” or other similar terminology, these terms are intended to indicate that a specific feature, structure, function, operation, or characteristic described in connection with the embodiment is found in at least one embodiment of the present disclosure. Therefore, the appearances of phrases such as “in one embodiment,” “in an embodiment,” “in an exemplary embodiment,” etc., may, but do not necessarily, all refer to the same embodiment, but rather, mean “one or more but not all embodiments” unless expressly specified otherwise. Further, the terms “comprising,” “having,” “including,” and variations thereof, are used in an open-ended manner and, therefore, should be interpreted to mean “including, but not limited to ...” unless expressly specified otherwise. Also, an element that is preceded by “comprises ... a” does not, without more constraints, preclude the existence of additional identical elements in the subject process, method, system, article, or apparatus that includes the element.

The terms “a,” “an,” and “the” also refer to “one or more” unless expressly specified otherwise. By way of example, “a processor” programmed to perform various functions refers to one processor programmed to perform each and every function or more than one processor collectively programmed to perform each of the various functions. In addition, the phrase “at least one of A and B” as may be used herein and/or in the following claims, whereby A and B are variables indicating a particular object or attribute, indicates a choice of A or B, or both A and B, similar to the phrase “and/or.” Where more than two variables are present in such a phrase, this phrase is hereby defined as including only one of the variables, any one of the variables, any combination (or sub-combination) of any of the variables, and all of the variables.

Further, where used herein, the term “about” or “approximately” applies to all numeric values, whether or not explicitly indicated. These terms generally refer to a range of numeric values that one of skill in the art would consider equivalent to the recited values (e.g., having the same function or result). In certain instances, these terms may include numeric values that are rounded to the nearest significant figure.

In addition, any enumerated listing of items that is set forth herein does not imply that any or all of the items listed are mutually exclusive and/or mutually inclusive of one another, unless expressly specified otherwise. Further, the term “set,” as used herein, shall be interpreted to mean “one or more,” and in the case of “sets,” shall be interpreted to mean multiples of (or a plurality of) “one or more,” “ones or more,” and/or “ones or mores” according to set theory, unless expressly specified otherwise.

The foregoing detailed description has been presented for purposes of illustration and description. It is not intended to be exhaustive or be limited to the precise form disclosed. Many modifications and variations are possible in light of the above description. The described embodiments were chosen to best explain the principles of the technology and its practical application to thereby enable others skilled in the art to best utilize the technology in various embodiments and with various modifications as are suited to the particular use contemplated. The scope of the technology is defined by the claims appended hereto.

What is claimed is:

1. A method of programming a memory device, comprising the steps of:
preparing a plurality of memory blocks, each of the memory blocks including an array of memory cells that are arranged in a plurality of word lines;
in a selected memory block of the plurality of memory blocks, in a first programming pass, programming foggy data into the memory cells of a selected word line of the plurality of word lines;
in at least one parity memory block of the plurality of memory blocks, programming two pages of parity data;
reading the foggy data to retrieve two pages pages of user data;
reading the parity data to retrieve two other pages of user data; and
combining the two pages of user data from the foggy data and the two other pages of user data to recreate four pages of user data.

2. The method as set forth in claim 1, further including the step of in a second programming pass, programming the memory cells of the selected word line from the foggy data to the user data.

3. The method as set forth in claim 2, wherein the step of reading the foggy data to retrieve the two pages of user data includes performing sensing operations at no more than three read levels.

4. The method as set forth in claim 2, wherein the step of, in the first programming pass, programming the foggy data into the memory cells of the selected word line further includes performing a plurality of verify operations at only three checkpoint data states.

5. The method as set forth in claim 4, wherein the step of, in the first programming pass, programming the foggy data into the memory cells of the selected word line further includes performing at least one program loop that includes a programming pulse and does not include a verify pulse.

6. The method as set forth in claim 2, wherein following the first pass, the memory cells of the selected word line are divided into four groups and the groups are divided into different threshold voltage ranges.

7. The method as set forth in claim 6, wherein prior to the second programming pass, the method further includes the step of, in a single programming pulse, inhibiting some of the memory cells of one of the four groups, programming some of the memory cells of the one of the four groups at a first rate, and programming some of the memory cells of the one of the four groups at a second rate that is greater than the first rate.

8. A memory device, comprising:
a plurality of memory blocks, each of the memory blocks including an array of memory cells that are arranged in a plurality of word lines; and
circuitry that is configured to program four pages of user data into the memory cells of a selected word line of the plurality of word lines and of a selected memory block of the plurality of memory blocks in a multi-pass programming operation, the circuitry being configured to;
in a first programming pass, program foggy data into the memory cells of the selected word line,
in at least one parity memory block of the plurality of memory blocks, program two pages of parity data,
read the foggy data to retrieve two pages of user data,
read the parity data to retrieve two other pages of user data, and
combine the two pages of user data from the foggy data and the two other pages of user data to recreate four pages of user data.

9. The memory device as set forth in claim 8, wherein during a second programming pass, the circuitry is further configured to program the memory cells of the selected word line from the foggy data to the user data.

10. The memory device as set forth in claim 9, wherein when reading the foggy data to retrieve the two pages of user data, the circuitry performs sensing operations at no more than three read levels.

11. The memory device as set forth in claim 9, wherein while programming the foggy data into the memory cells of the selected word line, the circuitry is further configured to perform a plurality of verify operations at only three checkpoint data states.

12. The memory device as set forth in claim 11, wherein while programming the foggy data into the memory cells of the selected word line, the circuitry is configured to perform at least one program loop that includes a programming pulse and does not include a verify pulse.

13. The memory device as set forth in claim 9, wherein following the first pass, the memory cells of the selected word line are divided into four groups and the groups are divided into different threshold voltage ranges.

14. The memory device as set forth in claim 13, wherein prior to the second programming pass, the circuitry is configured to, in a single programming pulse, inhibit some of the memory cells of one of the four groups, program some of the memory cells of the one of the four groups at a first rate, and program some of the memory cells of the one of the four groups at a second rate that is greater than the first rate.

15. An apparatus, comprising:
a plurality of memory blocks, each of the memory blocks including an array of memory cells that are arranged in a plurality of word lines; and
a programming means for programming the memory cells of a selected word line of the plurality of word lines to include four pages of user data per memory cell in a first programming pass and a second programming pass, the programming means being configured to;
in a first programming pass, program foggy data into the memory cells of the selected word line, the foggy data including two pages of the four pages of user data,
in at least one parity memory block of the plurality of memory blocks, program two pages of parity data, the two pages of parity data including two other pages of the four pages of user data,
read the foggy data to retrieve the two pages of user data,
read the parity data to retrieve the two other pages of user data,
combine the two pages of user data from the foggy data and the two other pages of user data to recreate the four pages of user data, and
in a second programming pass, program the other two pages of user data into the selected word line.

16. The apparatus as set forth in claim 15, wherein when reading the foggy data to retrieve the two pages of user data, the programming means performs sensing operations at no more than three read levels.

17. The apparatus as set forth in claim 15, wherein while programming the foggy data into the memory cells of the selected word line, the programming means is further configured to perform a plurality of verify operations at only three checkpoint data states.

18. The apparatus as set forth in claim 17, wherein while programming the foggy data into the memory cells of the selected word line, the programming means is configured to perform at least one program loop that includes a programming pulse and does not include a verify pulse.

19. The apparatus as set forth in claim 15, wherein following the first pass, the memory cells of the selected word line are divided into four groups and the groups are divided into different threshold voltage ranges.

20. The apparatus as set forth in claim 19, wherein prior to the second programming pass, the programming means is configured to, in a single programming pulse, inhibit some of the memory cells of one of the four groups, program some of the memory cells of the one of the four groups at a first rate, and program some of the memory cells of the one of the four groups at a second rate that is greater than the first rate.
